(19) United States
(12) Patent Application Publication
(10) Pub. No.: US 2026/0271686 A1
(43) Pub. Date: Sep. 10, 2026

(54) SEMICONDUCTOR DEVICE WITH A FIRST ISOLATION TRENCH AND METHOD OF MANUFACTURING

(71) Applicant: Infineon Technologies AG, Neubiberg (DE)

(72) Inventors: Donald Ray Disney, Muenchen (DE); Rolf Weis, Dresden (DE); Till Schlösser, München (DE)

(21) Appl. No.: 19/442,047

(22) Filed: Jan. 7, 2026

(30) Foreign Application Priority Data
Jan. 13, 2025 (DE) 102025100866.3

(51) Int. Cl. H10W 10/17; H10W 10/00

(52) U.S. Cl. CPC H10W 10/17; H10W 10/0143; H10W 10/0148

(57) ABSTRACT

A semiconductor device includes a lower semiconductor substrate layer of a first conductivity type and an upper semiconductor substrate layer. A patterned buried semiconductor substrate layer interposed between the lower and upper semiconductor substrate layers includes a first portion of a second conductivity type, a second portion of the second conductivity type laterally spaced apart from the first portion, and an intermediate region arranged laterally between the first and second portions. An isolation trench formed at an upper main surface of the upper semiconductor substrate layer extends in a vertical direction through the upper semiconductor substrate layer and the intermediate region, into the lower semiconductor substrate layer. The isolation trench is spaced apart from the first and second portions of the patterned buried semiconductor substrate layer, includes a first insulating material formed at an inner sidewall of the isolation trench, and is filled with an electrically conductive material.

### TECHNICAL FIELD

The present disclosure relates to semiconductor devices with a first isolation trench, and methods of manufacturing a semiconductor device.

### BACKGROUND

Integrated power technologies have evolved to where entire electronic systems are built into a single integrated circuit chip. The single chip combines analog, digital/logic and/or power functions to provide system functions. The single chip replaces multiple integrated circuit chips and enables manufacturers to build smaller systems. Applications include systems in the automotive, industrial, telecommunication, and data processing fields. The single chip can be manufactured via a bipolar, complementary metal oxide semiconductor (CMOS), double-diffused metal oxide semiconductor (DMOS) process, referred to as a BCD process. Within the single chip, an electrical isolation is required between parts of the chip operating at different voltage levels. For example, an electrical isolation is required between blocks operating at a high voltage and blocks operating at a lower voltage.

### SUMMARY

According to an example of a semiconductor device, the semiconductor device comprises a lower semiconductor substrate layer of a first conductivity type and an upper semiconductor substrate layer. The semiconductor device further comprises a patterned buried semiconductor substrate layer interposed between the lower semiconductor substrate layer and the upper semiconductor substrate layer. The patterned buried semiconductor substrate layer comprises a first portion of a second conductivity type, a second portion of the second conductivity type that is laterally spaced apart from the first portion, and an intermediate region arranged laterally between the first portion and the second portion. The semiconductor device further comprises a first isolation trench formed at an upper main surface of the upper semiconductor substrate layer and extending in a vertical direction through the upper semiconductor substrate layer and through the intermediate region of the patterned buried semiconductor substrate layer into the lower semiconductor substrate layer. The first isolation trench is spaced apart from the first portion of the patterned buried semiconductor substrate layer and from the second portion of the patterned buried semiconductor substrate layer. The first isolation trench comprises a first insulating material formed at an inner sidewall of the first isolation trench, and the first isolation trench is filled with a first electrically conductive material.

According to an example of a method of manufacturing a semiconductor device, the method comprises forming a buried semiconductor substrate layer over a lower semiconductor substrate layer of a first conductivity type. The method further comprises patterning the buried semiconductor substrate layer to form a first portion of a second conductivity type, a second portion of the second conductivity type that is laterally spaced apart from the first portion, and an intermediate region that is arranged laterally between the first portion and the second portion. The method further comprises forming an upper semiconductor substrate layer over the patterned buried semiconductor substrate layer. The method further comprises forming a first isolation trench extending in a vertical direction from an upper main surface of the upper semiconductor substrate layer through the upper semiconductor substrate layer and through the intermediate region of the patterned buried semiconductor substrate layer into the lower semiconductor substrate layer. The first isolation trench is spaced apart from the first portion of the patterned buried semiconductor substrate layer and from the second portion of the patterned buried semiconductor substrate layer. The method further comprises forming a first insulating material which covers an inner sidewall of the first isolation trench, and filling the first isolation trench with a first electrically conductive material.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements unless indicated otherwise. The elements of the drawings are not necessarily drawn to scale relative to each other. The features of the various illustrated examples can be combined unless they exclude each other.

FIGS. 1A-1G illustrate partial cross-sectional views of exemplary semiconductor devices;

FIGS. 2A and 2B illustrate partial top views of exemplary semiconductor devices;

FIG. 3A-3I, 4A-4G, 5A-5F illustrate a series of cross-sectional views of exemplary methods of manufacturing a semiconductor device;

FIG. 6 illustrates a partial cross-sectional view of an exemplary semiconductor device; and

FIGS. 7A-7G, 8A-8H, 9A-9E illustrate a series of cross-sectional views of exemplary methods of manufacturing a semiconductor device.

### DETAILED DESCRIPTION

The making and using of several examples are discussed in detail below. It should be appreciated, however, that the present invention provides many applicable inventive concepts that can be embodied in a wide variety of specific contexts. The specific examples discussed are merely illustrative of specific ways to make and use the invention, and do not limit the scope of the invention.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

The terms “on” and “over” are not to be construed as meaning only “directly on” and “directly over”. Rather, if one element is positioned “on” or “over” another element (e. g., a layer is “on” or “over” another layer or “on” or “over” a substrate), a further component (e. g., a further layer) may be positioned between the two elements (e. g., a further layer may be positioned between a layer and a substrate if the layer is “on” or “over” said substrate).

Spatially relative terms, such as “beneath”, “below”, “lower”, “above”, “upper”, “under” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

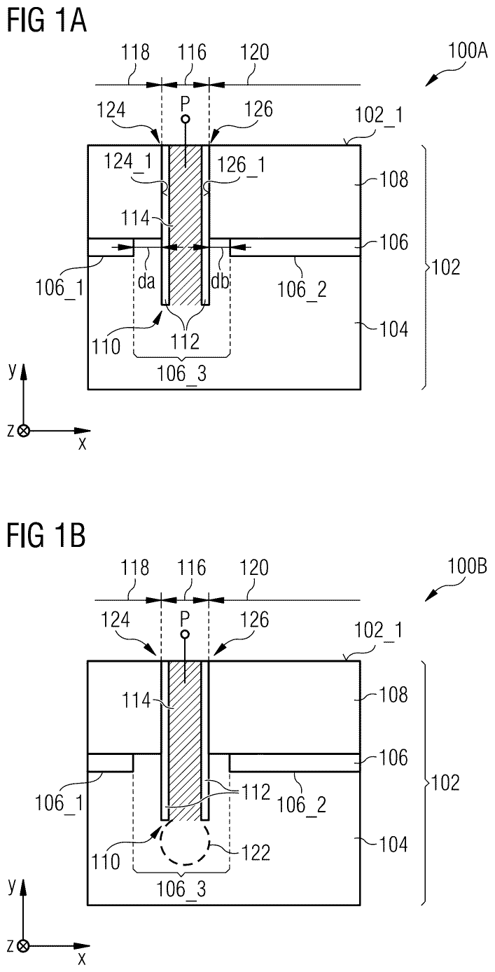

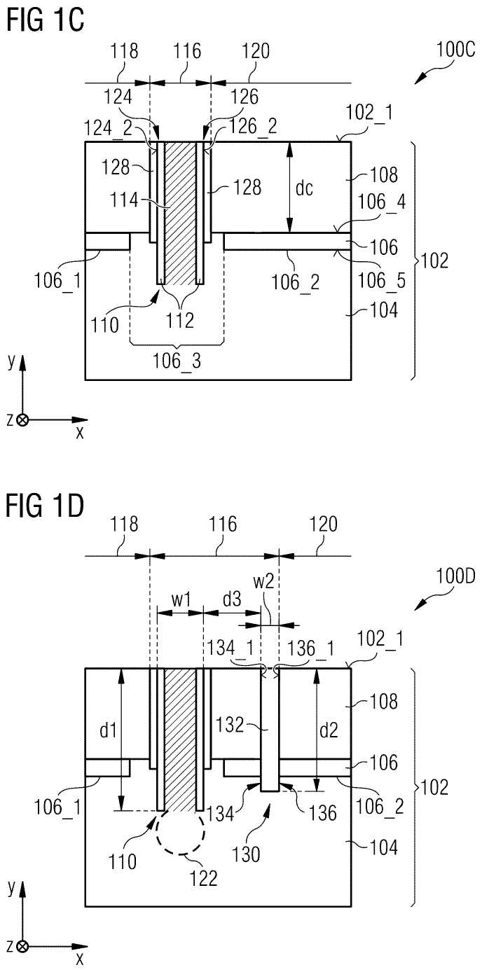

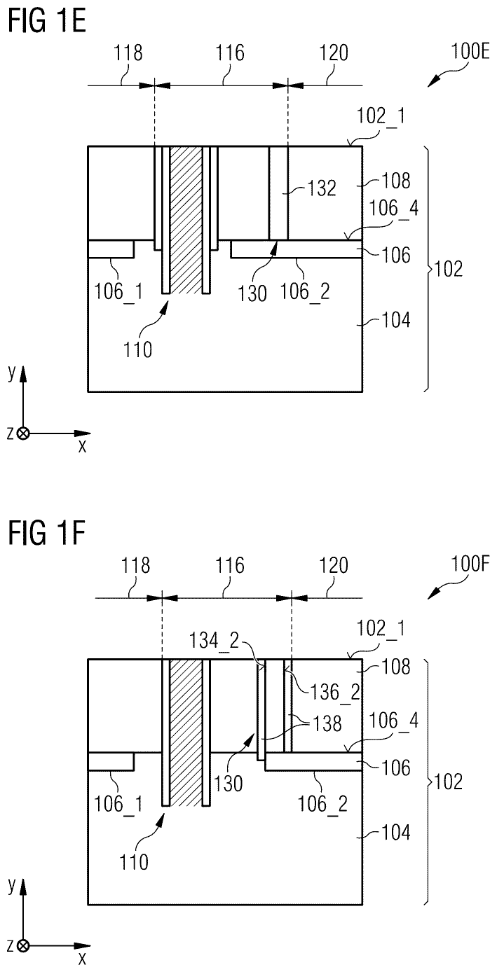

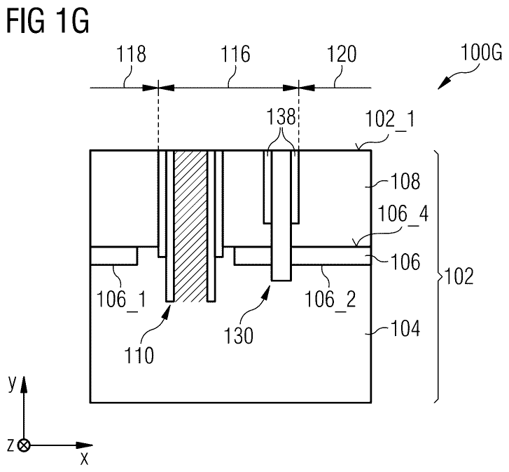

FIG. 1A schematically illustrates a partial cross-sectional view of an exemplary semiconductor device 100A. The semiconductor device 100A includes a semiconductor substrate 102. The semiconductor substrate 102 may include one or more of a variety of semiconductor materials that are used to form semiconductor devices. For example, the semiconductor substrate 102 may include single element semiconductors (e. g. Si, Ge, etc.), silicon-on-insulator semiconductors, binary semiconductors (e. g. SiC, GaN, GaAs, SiGe, etc.), ternary semiconductors (e. g. AlGaN, InGaAs, InAlAs, etc.). The semiconductor substrate 102 has a first main surface 102_1 and a second main surface (not illustrated) opposite the first main surface 102_1. The first main surface 102_1 may be referred to as a front surface and the second main surface may be referred to as a back surface. A first direction x is parallel to the first main surface 102_1 of the semiconductor substrate 102. The first direction x may be referred to as a horizontal direction, a lateral direction x, or an x-direction.

The semiconductor substrate 102 includes a lower semiconductor substrate layer 104 of a first conductivity type and an upper semiconductor substrate layer 108. An upper main surface 102_1 of the upper semiconductor substrate layer 108 coincides with the first main surface 102_1 of the semiconductor substrate 102. The upper main surface 102_1 of the upper semiconductor substrate layer 108 may be referred to as a first main surface 102_1 of the upper semiconductor substrate layer 108. The semiconductor substrate 102 further includes a buried semiconductor substrate layer 106 of a second conductivity type that is opposite to the first conductivity type. The buried semiconductor substrate layer 106 is interposed between the lower semiconductor substrate layer 104 and the upper semiconductor substrate layer 108 in a second direction y which is perpendicular to the first direction x. The second direction y may be referred to as a vertical direction y or a y-direction.

The buried semiconductor substrate layer 106 is a conductive layer that may be formed by implantation of dopants into the semiconductor substrate 102, deposition of a doped semiconductor material, or epitaxial growth of semiconductor material, for example. The buried semiconductor substrate layer 106 may be referred to as a buried layer 106. In one example, the lower semiconductor substrate layer 104 is of p-type and has a lower dopant concentration than the buried layer 106 that is of n-type. The buried layer 106 may have a thickness in the y-direction in a range of 0.5 μm to 3 μm and a sheet resistance in a range of 5 to 50 ohms/square. The buried layer 106 may be positioned directly on the lower semiconductor substrate layer 104. Alternatively, one or more intermediate layers may be interposed between the buried layer 106 and the lower semiconductor substrate layer 104. The buried layer 106 is a patterned buried layer 106 that includes a first portion 106_1 of the second conductivity type, a second portion 106_2 of the second conductivity type and an intermediate region that is arranged laterally between the first portion 106_1 and the second portion 106_2. That means, the intermediate region 106_3 separates the first portion 106_1 from the second portion 106_2 in the lateral direction x. The first portion 106_1 and the second portion 106_2 have, within manufacturing tolerances, a constant doping concentration along the x-direction. The doping of the intermediate region 106_3 varies in the x-direction, comprising regions of the second conductivity type diffused laterally out of the first portion 106_1 and the second portion 106_2. The doping concentration of the intermediate region 106_3 decreases in the x-direction starting from the first portion 106_1 and from the second portion 106_2, respectively, towards the middle of the intermediate region 106_3. In one example, the doping concentration decreases by one order of magnitude. The intermediate region 106_3 may be produced in a way that the intermediate region 106_3 is covered by a photoresist while the first portion 106_1 and the second portion 106_2 of the patterned buried layer 106 are implanted. The intermediate region 106_3 may also comprise a region of the first conductivity type laterally separating regions of the second conductivity type.

The upper semiconductor substrate layer 108 may be positioned directly on the patterned buried layer 106. Alternatively, one or more intermediate layers may be interposed between the upper semiconductor substrate layer 108 and the patterned buried layer 106. The upper semiconductor substrate layer 108 is a conductive layer that may be formed by epitaxial growth of semiconductor material, for example. The upper semiconductor substrate layer 108 may be of the first conductivity type or the second conductivity type. In one example, the upper semiconductor substrate layer 108 has the same conductivity type as the patterned buried layer 106 and has a lower dopant concentration than the patterned buried layer 106. In another example, the upper semiconductor substrate layer 108 has the opposite conductivity type of the patterned buried layer 106 and has a lower dopant concentration than the patterned buried layer 106. A doping concentration of the upper semiconductor layer 108 may be in a range of 1e14 cm−3 to 5e16 cm−3. A thickness of the upper semiconductor layer 108 may be in a range of 4 μm to 20 μm. The upper semiconductor substrate layer 108 includes well regions and/or doped regions that form part of functional devices that are at least partly formed within the upper semiconductor substrate layer 108. The functional devices may be active or a passive semiconductor devices.

As illustrated in FIG. 1A, a first isolation trench 110 is provided at the first main surface 102_1 of the upper semiconductor substrate layer 108. The first isolation trench 110 extends in the vertical direction y through the upper semiconductor substrate layer 108 and through the intermediate region 106_3 of the patterned buried semiconductor substrate layer 106 into the lower semiconductor substrate layer 104. That means, starting from the first main surface 102_1 of the upper semiconductor substrate layer 108, the first isolation trench 110 penetrates the upper semiconductor substrate layer 108 and extends through the intermediate region 106_3 of the patterned buried semiconductor substrate layer 106 into the lower semiconductor substrate layer 104. A bottom of the first isolation trench 110 resides within the lower semiconductor substrate layer 104. That means, the bottom of the first isolation trench 110 does not reach a lower surface of the lower semiconductor substrate layer 104. The first isolation trench 110 may be referred to as a deep trench isolation (DTI).

As further illustrated in FIG. 1A, the first isolation trench 110 is laterally spaced apart from the first portion 106_1 of the patterned buried semiconductor substrate layer 106 and from the second portion 106_2 of the patterned buried semiconductor substrate layer 106. The first isolation trench 110 is spaced at a first distance da from the first portion 106_1 of the patterned buried semiconductor substrate layer 106 in the lateral direction x. Besides, the first isolation trench 110 is spaced at a second distance db from the second portion 106_2 of the patterned buried semiconductor substrate layer 106 in the lateral direction x. For example, the first distance da and/or the second distance db is less than 20 μm, for example, it may range from 3 μm to 15 μm.

As further illustrated in FIG. 1A, the first isolation trench 110 contains a first insulating material 112 that lines an inner sidewall 124_1, 126_1 of the first isolation trench 110. The first insulating material 112 may be referred to as a liner. The first insulating material 112 may include grown and/or deposited oxide, nitride, or other dielectric material, for example. Moreover, the first isolation trench 110 is filled with a first electrically conductive material 114. The first electrically conductive material 114 may include highly doped polysilicon, a metal-semiconductor compound, a metal, and/or a metal alloy. In one example, the first electrically conductive material 114 is polysilicon and has the same conductivity type as the lower semiconductor substrate layer 104 and has a higher dopant concentration than the lower semiconductor substrate layer 104, for example 1e17 cm−3 to 1e20 cm−3. The first electrically conductive material 114 is separated laterally from the upper semiconductor substrate layer 108 and from the lower semiconductor substrate layer 104 by the first insulating material 112. A bottom portion of the first isolation trench 110 is devoid of any insulating material 112 and therefore, the first electrically conductive material 114 is in contact with the lower semiconductor substrate layer 104 at the bottom portion of the first isolation trench 110.

In the example of FIG. 1A, the lower semiconductor substrate layer 104 is configured to be set to an electrical potential P via the first electrically conductive material 114 and via an opening of the first insulating material 112 at the bottom of the first isolation trench 110. In one example, the lower semiconductor substrate layer 104 is configured to be set to a voltage supply potential P and/or a ground potential P. By biasing the lower semiconductor substrate layer 104 to a defined voltage potential P, e.g., to the ground potential P, the formation of a parasitic device within the semiconductor device 100A may be suppressed or deteriorated. In one example, the first electrically conductive material 114 is configured to be set to the ground potential P or to a low voltage potential to bias the lower semiconductor substrate layer 104. A current gain of a parasitic bipolar transistor having the lower semiconductor substrate layer 104 as a base is reduced. It is to be noted that FIG. 1A shows a schematic representation of the connection of the first electrically conductive material 114 to the electrical potential P. For ease of illustration, electrically conductive layers that are formed over the semiconductor substrate 102 and that form part of this connection are not illustrated in FIG. 1A. While in the example of FIG. 1A the lower semiconductor substrate layer 104 is configured to be set to the electrical potential P via the first electrically conductive material 114 and via an opening of the first insulating material 112 at the bottom of the first isolation trench 110, in other examples, the lower semiconductor substrate layer 104 is configured to be set to the electrical potential P in a different way, e. g., by using a sinker.

As further illustrated in FIG. 1A, the first isolation trench 110 is arranged in an interface region 116 of the semiconductor device 100A. In one example, the first isolation trench 110 has a lengthwise extension within the interface region 116 along the first main surface 102_1 of the upper semiconductor substrate layer 108 in a third direction z that is perpendicular to the first direction x and to the second direction y. The third direction z may be referred to as a further horizontal or a further lateral direction z. The interface region 116 separates a first functional device region 118 from a second functional device region 120. The first functional device region 118 is distinct from the second functional device region 120. The first functional device region 118, the second functional device region 120 and the interface region 116 are monolithically integrated in a same semiconductor die. The interface region 116 is arranged between the first functional device region 118 and the second functional device region 120. The first functional device region 118 includes at least one active or passive semiconductor device and the second functional device region 120 includes at least one active or passive semiconductor device. In one example, the passive semiconductor device may be at least one of an inductor, a capacitor, or a resistor. In one example, the active semiconductor device may be at least one of a transistor, or a diode, e. g., a power transistor, or a power diode. The at least one active or passive semiconductor device of the first functional device region 118 and the second functional device region 120 may be implemented using a mixed technology. Such a mixed technology may be used, for example, to form analog circuit blocks using bipolar devices, to form digital circuit blocks using CMOS (Complementary Metal Oxide Semiconductor) devices, and to form low-, medium-or high-voltage or power blocks using DMOS (Double-Diffused Metal Oxide Semiconductor) devices. Such a mixed technology is known, for example, as BCD (Bipolar CMOS DMOS) technology or SPT (Smart Power Technology) or BiCMOS technology when combining Bipolar and CMOS technology.

The first functional device region 118 includes well regions and/or doped regions in the upper semiconductor substrate layer 108 that form parts of the at least one active or passive semiconductor device of the first functional device region 118. Similarly, the second functional device region 120 includes well regions and/or doped regions in the upper semiconductor substrate layer 108 that form parts of the at least one active or passive semiconductor device of the second functional device region 120. In one example, the at least one active or passive semiconductor device of the first functional device region 118 is configured to operate at a different voltage level than the at least one active or passive semiconductor device of the second functional device region 120. In one example, the at least one active or passive semiconductor device of the first functional device region 118 has a different breakdown voltage than the at least one active or passive semiconductor device of the second functional device region 120. Besides, the first portion 106_1 of the patterned buried semiconductor substrate layer 106 in the first functional device region 118 is configured to be biased to a different voltage level than the second portion 106_2 of the patterned buried semiconductor substrate layer in the second functional device region 120. In one example, the first portion 106_1 of the patterned buried semiconductor substrate layer 106 in the first functional device region 118 and the second portion 106_2 of the patterned buried semiconductor substrate layer in the second functional device region 120, respectively, are configured to biased by connecting them to a voltage potential via sinkers as will be described in more detail below.

In one example, the active or passive semiconductor device of the second functional device region 120 is configured to operate at a higher voltage level than the active or passive semiconductor device of the first functional device region 118. That means, the active or passive semiconductor device included in the second functional device region 120 has a higher operating voltage or a higher operating range than the active or passive semiconductor device included in the first functional device region 118. During operation of the semiconductor device 100A, the upper semiconductor substrate layer 108 in the second functional device region 120 is at a higher voltage level than the upper semiconductor substrate layer 108 in the first functional device region 118. Similarly, the second portion 106_2 of the patterned buried semiconductor substrate layer in the second functional device region 120 is biased to a higher voltage level than the first portion 106_1 of the patterned buried semiconductor substrate layer 106 in the first functional device region 118. In one example, the active or passive semiconductor device of the second functional device region 120 is rated to operate at a voltage in a range of 40 V to 200V or even higher. In one example, the active or passive semiconductor device of the first functional device region 118 is rated to operate at a voltage in a range of 1.5 V to 40 V.

The first isolation trench 110 electrically isolates the first functional device region 118 from the second functional device region 120. More specific, the first isolation trench 110 separates the upper semiconductor substrate layer 108 in the second functional device region 120 from the upper semiconductor substrate layer 108 in the first functional device region 118. Besides, the first isolation trench 110 extends through the intermediate region 106_3 of the patterned buried semiconductor substrate layer 106. A first sidewall 124 of the first isolation trench 110 is arranged at a first distance da from the first portion 106_1 of the patterned buried semiconductor substrate layer 106. A second sidewall 126 that is opposite to the first sidewall 124 is arranged at a second distance db from the first portion 106_1 of the patterned buried semiconductor substrate layer 106. The first distance da may be same or different than the second distance db. Placing the first isolation trench 110 spaced apart from the first portion 106_1 of the patterned buried semiconductor substrate layer 106 and from the second portion 106_2 of the patterned buried semiconductor substrate layer 106 reduces an electric field density at a pn-junction that is formed between the patterned buried semiconductor substrate layer 106 and the lower semiconductor substrate layer 104. By reducing the electric field density at the pn-junction, a breakdown at the pn-junction may be avoided and/or a breakdown voltage of the pn-junction may be increased. For example, the breakdown of the pn-junction may be prevented in implementation examples where the first electrically conductive material 114 is set to the ground potential P. At the same time, the formation of the parasitic bipolar transistor having the lower semiconductor substrate layer 104 as a base is avoided as described above.

FIG. 1B schematically illustrates a further partial cross-sectional view of an exemplary semiconductor device 100B. The semiconductor device 100B of FIG. 1B is similar to the semiconductor device 100A as illustrated and described in connection with FIG. 1A. Differently, the lower semiconductor substrate layer 104 of the semiconductor device 100B of FIG. 1B includes a region 122 that has a locally increased dopant concentration at the bottom of the first isolation trench 110. That means the region 122 has the same conductivity type as the lower semiconductor substrate layer 104 and has a higher dopant concentration than the lower semiconductor substrate layer 104. The region 122 allows for an improved electrical contact of the first electrically conductive material 114 to the lower semiconductor substrate layer 104.

FIG. 1C schematically illustrates a further partial cross-sectional view of an exemplary semiconductor device 100C. The semiconductor device 100C of FIG. 1C is similar to the semiconductor device 100A as illustrated and described in connection with FIG. 1A. Differently, semiconductor device 100C includes a first sinker 128 that is formed at the upper main surface 102_1 of the upper semiconductor substrate layer 108 and that extends in the vertical direction y along at least part of an outer sidewall 124_2, 126_2 of the first isolation trench 110. The first sinker 128 is of the second conductivity type and may be formed by ion implantation and/or diffusion as will be described in more detail below. A doping concentration of the first sinker 128 decreases along the lateral direction x. The first sinker 128 comprises a highly doped region that is formed at the outer sidewall 124_2, 126_2 of the first isolation trench 110. Within the highly doped region, the doping concentration decreases by less than one order of magnitude. The highly doped region of the first sinker 128 is spaced apart from the first portion 106_1 of the patterned buried semiconductor substrate layer 106 and from the second portion 106_2 of the patterned buried semiconductor substrate layer 106. The first sinker 128 extends from the upper main surface 102_1 of the upper semiconductor substrate layer 108 at least to a depth dc defined by an upper main surface 106_4 of the patterned buried semiconductor substrate layer 106. In the example of FIG. 1C, the first sinker 128 extends deeper than the depth dc but does not extend to a depth defined by a lower main surface 106_5 of the patterned buried semiconductor substrate layer 106. The example of FIG. 1C may be combined with the example of FIG. 1B and the region 122 having a locally increased dopant concentration may be formed at the bottom of the first isolation trench 110 of FIG. 1C.

FIG. 1D-1G schematically illustrates further partial cross-sectional views of exemplary semiconductor devices 100D-100G that include the first isolation trench 110 of any of the examples as illustrated and described in connection with FIG. 1A-1C above. The semiconductor devices 100D-100G further include a second isolation trench 130 that is formed at the first main surface 102_1 of the upper semiconductor substrate layer 108 and that extends in the vertical direction y. The second isolation trench 130 includes a second insulating material 132 that is formed at an inner sidewall 134_1, 136_1 and a bottom of the second isolation trench 130. The second insulating material 132 may include grown and/or deposited oxide, nitride, or other dielectric material, for example. In the examples of FIGS. 1D-1G, the second isolation trench 130 is devoid of electrically conductive material. That means, the second isolation trench 130 does not contain any electrically conductive material. Instead, the second isolation trench 130 is completely filled with the second insulating material 132. In other examples, the second isolation trench 130 is filled partly with a second electrically conductive material (not illustrated). The second electrically conductive material may include highly doped polysilicon, a metal-semiconductor compound, a metal, and/or a metal alloy. The second electrically conductive material is separated from the semiconductor substrate 102 by the second insulating material 132.

The second isolation trench 130 is arranged in the interface region 116 and may have a lengthwise extension at least partly in parallel to the first isolation trench 110 along the first main surface 102_1 of the upper semiconductor substrate layer 108 in the third direction z. A first sidewall 134 of the second isolation trench 130 is opposite to a second sidewall 136 of the second isolation trench 130. The first isolation trench 110 and the second isolation trench 130 electrically isolate the first functional device region 118 from the second functional device region 120. More specific, the first isolation trench 110 and the second isolation trench 130 separate the upper semiconductor substrate layer 108 in the second functional device region 120 from the upper semiconductor substrate layer 108 in the first functional device region 118. The first isolation trench 110 and the second isolation trench 130 are configured to act as a kind of capacitive voltage divider that divides the higher operating voltage or higher voltage level of the second functional device region 120 down to a lower operating voltage or lower voltage level of the first functional device region 118. The first isolation trench 110 and the second isolation trench 130 may be referred to as a dual trench isolation structure or a double trench isolation structure. It is to be noted that in some examples, the interface region 116 may include further isolation trenches that are similar or same as the first isolation trench 110 and/or the second isolation trench 130.

In the examples of semiconductor devices 100D-100G, a region of the upper semiconductor substrate layer 108 between the first isolation trench 110 and the second isolation trench 130 is devoid of a functional device. That means, the upper semiconductor substrate layer 108 in the interface region 116 may not include any parts of active or passive semiconductor devices. A distance d3 between the first isolation trench 110 and the second isolation trench 130 is measured at a position at the first main surface 102_1 of the semiconductor substrate 102 along the first direction x. In one example, the distance d3 is in a range of 1 μm to 5 μm. In other examples (not illustrated), the second isolation trench 130 is arranged further apart from the first isolation trench 110 and the region of the upper semiconductor substrate layer 108 between the first isolation trench 110 and the second isolation trench 130 includes functional devices.

The first isolation trench 110 has a first width w1, the second isolation trench 130 has a second width w2 and the first width w1 is larger than the second width w2. The first width w1 and the second width w2 may be measured at a position at the first main surface 102_1 of the upper semiconductor substrate layer 108. In one example, the first width w1 is in a range of 2 μm to 5 μm and the second width w2 is in a range of 1 μm to 4 μm. Besides, the first isolation trench 110 has a first depth d1, the second isolation trench 130 has a second depth d2 and the first depth d1 is larger than the second depth d2. The first depth d1 and the second depth d2 may be measured starting from a position at the first main surface 102_1 of the upper semiconductor substrate layer 108 to the bottom of the first isolation trench 110 and the second isolation trench 130, respectively. In one example, as will be described in more detail below, the first isolation trench 110 and the second isolation trench 130 are manufactured in a same processing step. The second width w2 may be dimensioned in a way that the second isolation trench 130 is completely filled with the second insulating material 132. In contrast to that, the first width w1 is defined in a way that the first insulating material 112 covers only inner sidewalls of the first isolation trench 110.

In the exemplary semiconductor device 100D of FIG. 1D, the second isolation trench 130 extends through the upper semiconductor substrate layer 108 and through the patterned buried semiconductor substrate layer 106 into the lower semiconductor substrate layer 104. That means, starting from the first main surface 102_1 of the upper semiconductor substrate layer 108, the second isolation trench 130 penetrates the upper semiconductor substrate layer 108 and the patterned buried semiconductor substrate layer 106 and extends into the lower semiconductor substrate layer 104. A bottom of the second isolation trench 130 resides within the lower semiconductor substrate layer 104. There is no gap within the patterned buried semiconductor substrate layer 106 at a position where the second isolation trench 130 extends through the patterned buried semiconductor substrate layer 106. The second isolation trench 130 isolates a portion of the patterned buried semiconductor substrate layer 106 that is arranged in the second functional device region 120 from a portion of the patterned buried semiconductor substrate layer 106 that is arranged in the interface region 116.

In the exemplary semiconductor device 100E of FIG. 1E, the second isolation trench 130 extends through the upper semiconductor substrate layer 108 to the upper main surface 106_4 of the patterned buried semiconductor substrate layer 106 but does not extend through the patterned buried semiconductor substrate layer 106. In one example, the second isolation trench 130 extends through the upper semiconductor substrate layer 108 at least to the upper main surface 106_4 of the patterned buried semiconductor substrate layer 106 but does not extend through the patterned buried semiconductor substrate layer 106.

FIGS. 1F and 1G schematically illustrate further partial cross-sectional views of exemplary semiconductor devices 100F-100G that include the first isolation trench 110 of any of the examples as illustrated and described in connection with FIG. 1A-1C above and that includes the second isolation trench 130 of any of the examples as illustrated and described in connection with FIGS. 1D and 1E above. The semiconductor devices 100F and 100G include a second sinker 138 that is formed at the upper main surface 102_1 of the upper semiconductor substrate layer 108 and that extends in the vertical direction y along at least part of an outer sidewall 134_2, 136_2 of the second isolation trench 130. The second sinker 138 is of the second conductivity type and may be formed by ion implantation and/or diffusion as will be described in more detail below.

In the exemplary semiconductor device 100F of FIG. 1F, the second sinker 138 extends from the upper main surface 102_1 of the upper semiconductor substrate layer 108 through the upper semiconductor substrate layer 108 at least to the upper main surface 106_4 of the patterned buried semiconductor substrate layer 106. The second sinker 138 provides a low ohmic electrical connection to the patterned buried semiconductor substrate layer 106. The second sinker 138 may not extend through the patterned buried semiconductor substrate layer 106.

In the exemplary semiconductor device 100G of FIG. 1G, the second sinker 138 extends from the upper main surface 102_1 of the upper semiconductor substrate layer 108 into the upper semiconductor substrate layer 108. The second sinker 138 does not extend to the upper main surface 106_4 of the patterned buried semiconductor substrate layer 106.

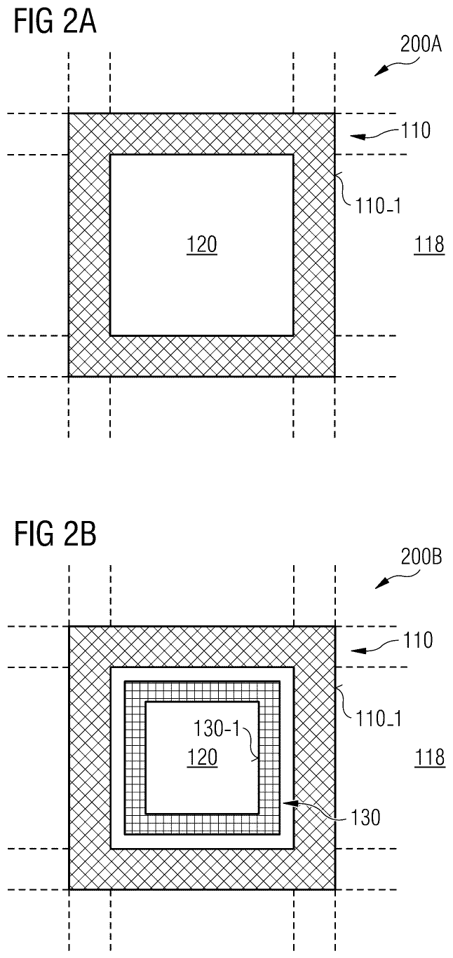

FIG. 2A schematically illustrates a partial top view of an exemplary semiconductor device 200A. The semiconductor device 200A includes a semiconductor device 100A-100C as illustrated and described in connection with FIG. 1A-1C above. The semiconductor device 200A includes the second functional device region 120 that is surrounded by the first isolation trench 110. The semiconductor device 200A further includes the first functional device region 118 that is located at a side 110_1 of the first isolation trench 110 that faces away from the second functional device region 120. While in the example of FIG. 2A the second functional device region 120 is completely surrounded by the first isolation trench 110, in other examples, the first isolation trench 110 is interrupted and/or segmented. That means, the first isolation trench 110 surrounds the second functional device region 120 at least partly. In a top view, the first isolation trench 110 may be ring-, round-, oval-, square-, rectangular-, trapezoidal-, or hexagonal-shaped, or may have other shapes.

In one example, an active or passive semiconductor device of the second functional device region 120 is configured to operate at a higher voltage level than an active or passive semiconductor device of the first functional device region 118. In other examples, this may be vice versa. In one example, there may be further isolation trenches that branch off from the first isolation trench 110 as indicated by dashed lines in FIG. 2A. Besides, there may be further functional device regions that operate at a same or different voltage level than the first functional device region 118 and/or the second functional device region 120.

FIG. 2B schematically illustrates a further partial top view of an exemplary semiconductor device 200B. The semiconductor device 200B of FIG. 2B is similar to the semiconductor device 200A as illustrated and described in connection with FIG. 2A. Differently, the semiconductor device 200B includes a second isolation trench 130 in addition to the first isolation trench 110 as illustrated and described in connection with the semiconductor devices 100D-100F of FIG. 1D-1F above. The semiconductor device 200B includes the second functional device region 120 that is surrounded by the second isolation trench 130. The semiconductor device 200B further includes the first isolation trench 110 that surrounds the second isolation trench 130. That means, the second functional device region 120 is located at the side 130_1 of the second isolation trench 130 that faces away from the first isolation trench 110. The semiconductor device 200B further includes the first functional device region 118 that is located at the side 110_1 of the first isolation trench 110 that faces away from the second isolation trench 130. A region between the first isolation trench 110 and the second isolation trench 130 does not include any functional device.

While in the example of FIG. 2B the second functional device region 120 is completely surrounded by the second isolation trench 130 and the second isolation trench 130 is completely surrounded by the first isolation trench 110, in other examples, the first isolation trench 110 and/or the second isolation trench 130 is interrupted and/or segmented. In one example, the second functional device region 120 is surrounded by the second isolation trench 130 at least partly. Similarly, the second isolation trench 130 is surrounded by the first isolation trench 110 at least partly. The first isolation trench 110 and the second isolation trench 130 may have a same or different shape. In a top view, the first isolation trench 110 and the second isolation trench 130 may be ring-, round-, oval-, square-, rectangular-, trapezoidal-, or hexagonal-shaped, or may have other shapes. While in the example of FIG. 2B the first isolation trench 110 runs in parallel with the second isolation trench 130, in other examples, the first isolation trench 110 and the second isolation trench 130 do not run parallel to each other. In one example, one or more further isolation trenches may be provided between the first functional device region 118 and the second functional device region 120. The one or more further isolation trenches may be similar or same as the first isolation trench 110 and/or the second isolation trench 120. The one or more further isolation trenches may provide for an improved electrical isolation of a functional device located in the first functional device region 118 from a functional device located in the second functional device region 120.

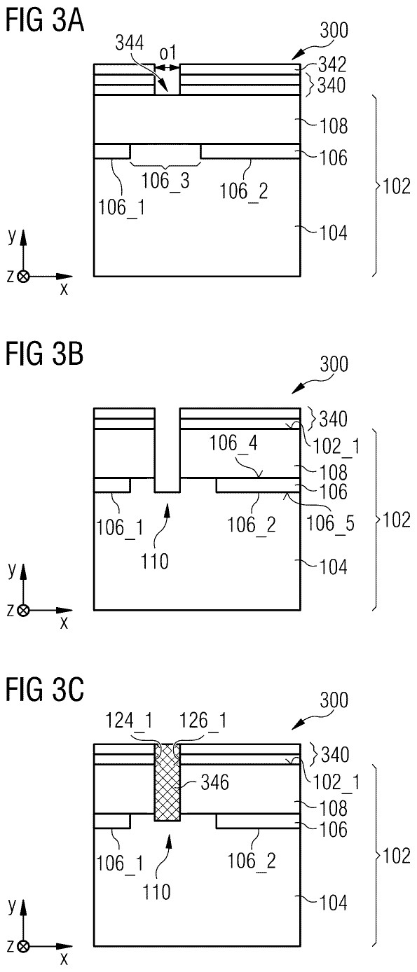

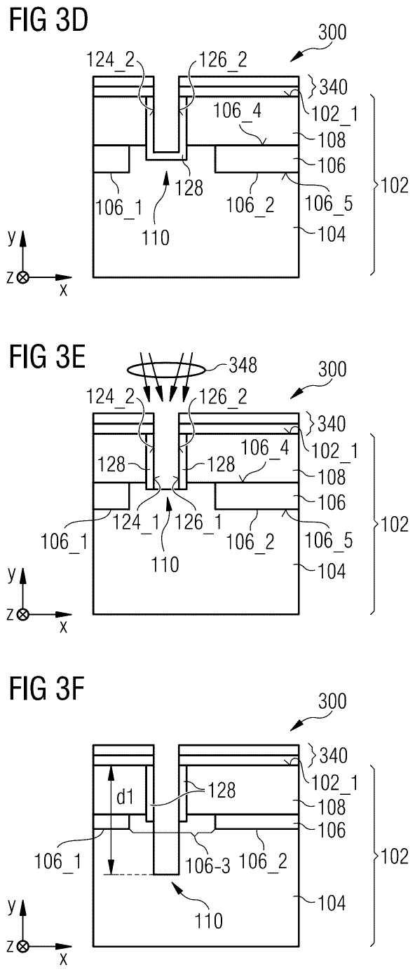

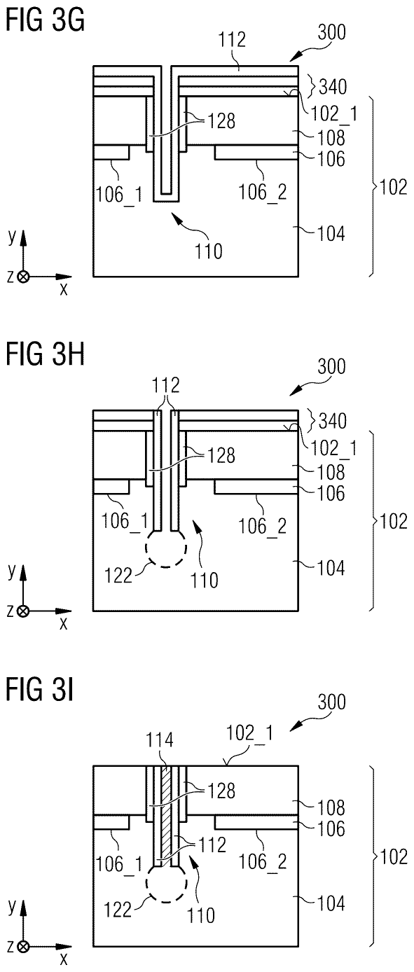

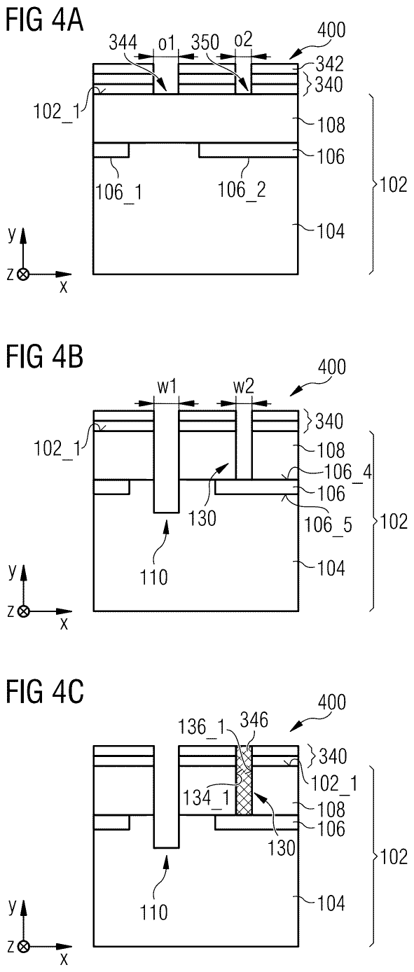

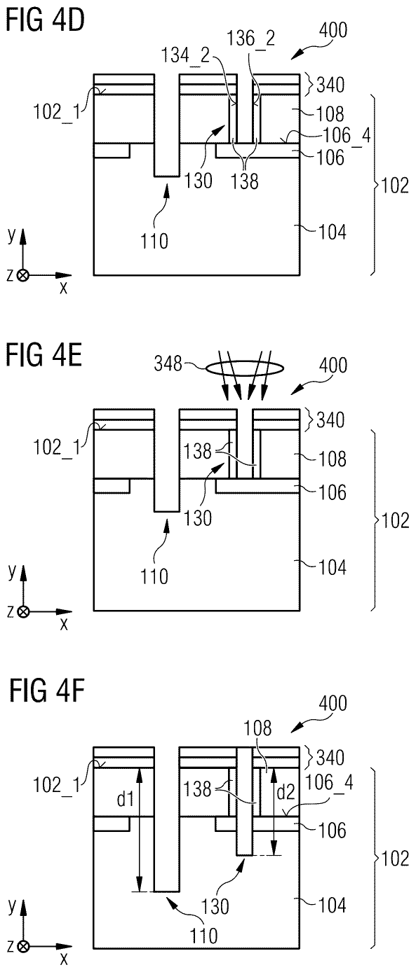

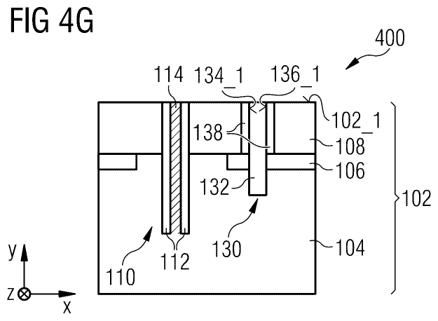

FIG. 3A-3I schematically illustrate a series of cross-sectional views of an exemplary method of manufacturing a semiconductor device 300. In one example, the method as will be described in connection with FIG. 3A-3I may be used to manufacture at least part of a semiconductor device similar to one of the semiconductor devices 100A-100G, 200A-200B as illustrated and described in connection with FIG. 1A-1G, 2A-2B above. In another example, the method as will be described in connection with FIG. 3A-3I may be used to manufacture at least part of a different semiconductor device.

As illustrated in FIG. 3A, a semiconductor substrate 102 is provided that includes a patterned buried semiconductor substrate layer 106 that is formed over a lower semiconductor substrate layer 104. The lower semiconductor substrate layer 104 has a first conductivity type. The patterned buried semiconductor substrate layer 106 includes a first portion 106_1 of a second conductivity type, a second portion 106_2 of the second conductivity type and an intermediate region 106_3 that is arranged laterally between the first portion 106_1 and the second portion 106_2. The second conductivity type is opposite to the first conductivity type. The lower semiconductor substrate layer 104 may be a bulk substrate, at least part of a silicon on insulator (SOI) substrate, or an epitaxial layer. The first portion 106_1 and the second portion 106_2 of the patterned buried semiconductor substrate layer 106 may be formed by implantation of at least one dopant, e.g., arsenic (As) and/or phosphor (P) into the semiconductor substrate 102, by in-situ deposition of a doped semiconductor material using, e. g., a chemical vapor deposition (CVD) process, and/or by epitaxial growth of a semiconductor material. The first portion 106_1 and the second portion 106_2 have, within manufacturing tolerances, a constant doping concentration along the x-direction. The doping of the intermediate region 106_3 varies in the x-direction, comprising regions of the second conductivity type diffused laterally out of the first portion 106_1 and the second portion 106_2. In one example, the doping concentration decreases by one order of magnitude. The intermediate region 106_3 may be produced in a way that the intermediate region 106_3 is covered by a photoresist while the first portion 106_1 and the second portion 106_2 of the patterned buried layer 106 are implanted. The intermediate region 106_3 may also comprise a region of the first conductivity type laterally separating regions of the second conductivity type.

The semiconductor substrate 102 further includes an upper semiconductor substrate layer 108 that is formed over the patterned buried semiconductor substrate layer 106. In one example, the upper semiconductor substrate layer 108 has the second conductivity type and a lower dopant concentration than the patterned buried semiconductor substrate layer 106. In other examples, the upper semiconductor substrate layer 108 has the first conductivity type and/or a different dopant concentration. The upper semiconductor substrate layer 108 may be formed by deposition of a doped semiconductor material using, e. g., a chemical vapor deposition (CVD) process, and/or by epitaxial growth of a semiconductor material on top of the patterned buried semiconductor substrate layer 106.

A hard mask 340 is formed over the upper semiconductor substrate layer 108. The hard mask 340 may include one or several layers that include at least one of silicon nitride, oxide, polysilicon, borosilicate glass (BSG) or borophosphosilicate glass (BPSG). A mask layer 342 is formed over the hard mask 340. The mask layer 342 is structured to expose locations where a first isolation trench 110 is to be formed. The structured mask layer 342 includes a first opening having a first width o1 to form the first isolation trench 110. The first opening of the structured mask layer 342 is formed over the intermediate region 106_3 of the patterned buried semiconductor substrate layer 106. The mask layer 342 may include a photoresist, may be referred to as a photoresist layer and may be structured by using photolithography. FIG. 3A shows the semiconductor device 300 after an etching step has been performed. During the etching step, the mask layer 342 is used to form a first opening 344 in the hard mask 340. The opening 344 in the hard mask 340 extends through the hard mask 340 and a patterned hard mask 340 is provided.

FIG. 3B shows the semiconductor device 300 after the mask layer 342 has been removed and after a further etching step has been performed. This further etching step is a first etching step of a multiple step etching process. During the first etching step, the first isolation trench 110 is formed in the semiconductor substrate 102 by using the hard mask 340 as a mask layer. The first isolation trench 110 is etched to extend from the first main surface 102_1 of the upper semiconductor substrate layer 108 to an intermediate trench depth. In the example of FIG. 3B, the first isolation trench 110 extends through the upper semiconductor substrate layer 108 into the intermediate trench depth that is between the upper main surface 106_4 of the patterned buried semiconductor substrate layer 106 and the lower main surface 106_5 of the patterned buried semiconductor substrate layer 106. Generally, the first isolation trench 110 may not extend deeper than the lower main surface 106_5 of the patterned buried semiconductor substrate layer 106 after the first etching step. The first isolation trench 110 is spaced apart from the first portion 106_1 of the patterned buried semiconductor substrate layer 106 and from the second portion 106_2 of the patterned buried semiconductor substrate layer 106 after the first etching step. In one example (not illustrated), part of the hard mask 340 is removed during the first etching step of the multiple step etching process.

FIG. 3C-3E schematically illustrate a series of cross-sectional views of two different methods of manufacturing the first sinker 128 that extends from the upper main surface 102_1 of the upper semiconductor substrate layer 108 along at least part of an outer sidewall 124_2, 126_2 of the first isolation trench 110. In one example, the first sinker 128 extends from the upper main surface 102_1 of the upper semiconductor substrate layer 108 at least to a depth defined by an upper main surface 106_4 of the patterned buried semiconductor substrate layer 106. It is to be noted that the formation of the first sinker 128 is optional and there may be semiconductor devices 300 that do not have the first sinker 128. FIGS. 3C and 3D show the first method of forming the first sinker 128 using diffusion of PSG (phosphosilicate glass). FIG. 3E shows the second method of forming the first sinker 128 using ion implantation.

As illustrated in FIG. 3C, PSG 346 is formed to cover the inner sidewall 124_1, 126_1 and the bottom of the first isolation trench 110. In the example of FIG. 3C, the first isolation trench 110 is completely filled with PSG 346 that may be formed by a CVD process. FIG. 3D shows the semiconductor device 300 after phosphorous of the PSG 346 has outdiffused into the outer sidewall 124_2, 126_2 and the bottom of the first isolation trench 110 to form the first sinker 128 and after the PSG 346 has been removed. The PSG 346 may be removed by etching. It is to be noted that the first sinker 128 may also be formed using gas-phase diffusion instead of deposited PSG 346. The first sinker 128 is of the second conductivity type and extends along the outer sidewall 124_2, 126_2 of the first isolation trench 110. The first sinker 128 extends through the upper semiconductor substrate layer 108 to a depth that is between the upper main surface 106_4 of the patterned buried semiconductor substrate layer 106 and the lower main surface 106_5 of the patterned buried semiconductor substrate layer 106. The doping concentration of the first sinker 128 decreases along the lateral direction x. The first sinker 128 comprises a highly doped region that is formed at the outer sidewall 124_2, 126_2 of the first isolation trench 110. Within the highly doped region, the doping concentration decreases by less than one order of magnitude. The highly doped region of the first sinker 128 is spaced apart from the first portion 106_1 of the patterned buried semiconductor substrate layer 106 and from the second portion 106_2 of the patterned buried semiconductor substrate layer 106.

As mentioned above, FIG. 3E shows an alternative way of forming the first sinker 128. As illustrated in FIG. 3E, ions 348 are implanted through the inner sidewall 124_1, 126_1 of the first isolation trench into the outer sidewall 124_2, 126_2 of the first isolation trench 110 to form the first sinker 128. The ions may be dopants of the second conductivity type that include arsenic (As) and/or phosphor (P) and that may be implanted along the inner sidewall 124_1, 126_1 at a tilt angle. The first sinker 128 extends through the upper semiconductor substrate layer 108 to a depth that is between the upper main surface 106_4 of the patterned buried semiconductor substrate layer 106 and the lower main surface 106_5 of the patterned buried semiconductor substrate layer 106. The highly doped region of the first sinker 128 is spaced apart from the first portion 106_1 of the patterned buried semiconductor substrate layer 106 and from the second portion 106_2 of the patterned buried semiconductor substrate layer 106.

FIG. 3F shows the semiconductor device 300 after yet a further etching step has been performed. This further etching step is a second etching step of the multiple step etching process. During the second etching step, a trench depth of the first isolation trench 110 is extended using the hard mask 340 as a mask layer. After the second etching step, the first isolation trench 110 has its final first depth d1 and the second etching step is the final etching step of the multiple step etching process. The first isolation trench 110 extends through the upper semiconductor substrate layer 108 and through the intermediate region 106_3 of the patterned buried semiconductor substrate layer 106 into the lower semiconductor substrate layer 104. The first isolation trench 110 is spaced apart from the first portion 106_1 of the patterned buried semiconductor substrate layer 106 and from the second portion 106_2 of the patterned buried semiconductor substrate layer 106 after the second etching step.

As illustrated in FIG. 3G, the first insulating material 112 is formed that covers the inner sidewall 124_1, 126_1 and the bottom of the first isolation trench 110. The first insulating material 112 is further formed over a surface of the hard mask 340 that faces away from the first main surface 102_1 of the upper semiconductor substrate layer 108. The first insulating material 112 includes an electrically insulating material. In one example, the first insulating material 112 includes a dielectric material. In one example, the first insulating material 112 includes at least one of grown and/or deposited oxide or nitride. A chemical vapor deposition (CVD) process may be used for the deposition. In other examples, the first insulating material 112 includes other materials or other combinations of electrically insulating materials.

FIG. 3H shows the semiconductor device 300 after the first insulating material 112 has been removed from a bottom of the first isolation trench 110 to form an opening of the first insulating material 112 at the bottom of the first isolation trench 110. Besides, the first insulating material 112 is removed from the surface of the hard mask 340 that faces away from the first main surface 102_1 of the upper semiconductor substrate layer 108. The first insulating material 112 may be removed by using an etching process. FIG. 3H further shows the semiconductor device 300 after an optional processing step has been performed. In this optional processing step, dopants of the first conductivity type are introduced into the bottom of the first isolation trench 110, e. g., by a self-aligned ion implantation, to form the region 122 of the lower semiconductor substrate layer 104. The region 122 has a locally increased dopant concentration and is arranged at the bottom of the first isolation trench 110.

As illustrated in FIG. 3I, the first isolation trench 110 is filled with the first electrically conductive material 114. In one example, the first electrically conductive material 114 includes at least one of polysilicon or metal. In other examples, the first electrically conductive material includes other materials or other combinations of electrically conductive materials. The filling of the first isolation trench 110 comprises filling the first electrically conductive material 114 in the opening of the first insulating material 112 at the bottom of the first isolation trench 110 to provide a connection of the first electrically conductive material 114 to the lower semiconductor substrate layer 104. The lower semiconductor substrate layer 104 may be biased to a predefined voltage level via the first electrically conductive material 114 that extends through the opening of the first insulating material 112 at the bottom of the first isolation trench 110. It is to be noted that in other examples, in contrast to the illustration in FIG. 3H, the first insulating material 112 may not be removed from the bottom of the first isolation trench 110 and the first electrically conductive material 114 may not be connected to the lower semiconductor substrate layer 104 at the bottom of the first isolation trench 110. That means, the first electrically conductive material 114 is separated from the semiconductor substrate 102 by the first insulating material 112 at both, the sidewalls and the bottom. In this other example, the lower semiconductor substrate layer 104 may be configured to be set to an electrical potential in a different way, e. g., by using a sinker. As further illustrated in FIG. 3I, the hard mask 340 has been removed from the first main surface 102_1 of the upper semiconductor substrate layer 108. The hard mask 340 may be removed by using an etching process and/or a chemical mechanical polish (CMP) process.

FIG. 4A-4G schematically illustrate a series of cross-sectional views of an exemplary method of manufacturing a further semiconductor device 400. In one example, the method as will be described in connection with FIG. 4A-4G may be used to manufacture at least part of a semiconductor device similar to one of the semiconductor devices 100D-100G, 200B as illustrated and described in connection with FIG. 1D-1G, 2B above. In another example, the method as will be described in connection with FIG. 4A-4G may be used to manufacture at least part of a different semiconductor device.

The semiconductor device 400 of FIG. 4A is similar to the semiconductor device 300 of FIG. 3A. Differently, the structured mask layer 342 further includes a second opening having a second width o2 to form the second isolation trench 130. The first width o1 is larger than the second width o2. The second opening of the structured mask layer 342 is formed over the second portion 106_2 of the patterned buried semiconductor substrate layer 106. There is no intermediate region of the patterned buried semiconductor substrate layer 106 below the second opening of the structured mask layer 342. FIG. 4A shows the semiconductor device 400 after an etching step has been performed. During the etching step, the mask layer 342 is used to form a second opening 350 in the hard mask 340. The second opening 350 extends through the hard mask 340.

The semiconductor device 400 of FIG. 4B is similar to the semiconductor device 300 of FIG. 3B. Differently, also the second isolation trench 130 is etched to an intermediate trench depth during the first etching step of a two-step etching process. The second isolation trench 130 is formed in the semiconductor substrate 102 by using the hard mask 340 as a mask layer. The second isolation trench 130 is etched to extend from the first main surface 102_1 of the upper semiconductor substrate layer 108 to an intermediate trench depth. In the example of FIG. 4B, the second isolation trench 130 extends through the upper semiconductor substrate layer 108 to the upper main surface 106_4 of the patterned buried semiconductor substrate layer 106. In other examples, the second isolation trench 130 extends into the upper semiconductor substrate layer 108 but does not reach the upper main surface 106_4 of the patterned buried semiconductor substrate layer 106 after the first etching step. Generally, the second isolation trench 130 may not extend deeper than the lower main surface 106_5 of the patterned buried semiconductor substrate layer 106 after the first etching step. In the example of FIG. 4B, the first isolation trench 110 extends to an intermediate trench depth below the lower main surface 106_5 of the patterned buried semiconductor substrate layer 106 after the first etching step.

The first isolation trench 110 has the first width w1, the second isolation trench 130 has the second width w2 and the first width w1 is larger than the second width w2. The first width w1 and the second width w2 may be measured at a position at the first main surface 102_1 of the upper semiconductor substrate layer 108. The first isolation trench 110 has a first intermediate trench depth, the second isolation trench 130 has a second intermediate trench depth and the first intermediate trench depth is larger than the second intermediate trench depth. The first intermediate trench depth and the second intermediate trench depth may be measured starting from a position at the first main surface 102_1 of the upper semiconductor substrate layer 108 to the bottom of the first isolation trench 110 and the second isolation trench 130, respectively. The first isolation trench 110 has a larger intermediate trench depth than the second isolation trench 130 as a result of its width being larger than the width of the second isolation trench 130.

FIG. 4C-4E schematically illustrate a series of cross-sectional views of two different methods of manufacturing the second sinker 138 that extends from the upper main surface 102_1 of the upper semiconductor substrate layer 108 along at least part of an outer sidewall 134_2, 136_2 of the second isolation trench 130. It is to be noted that the formation of the second sinker 138 is optional and there may be semiconductor devices 400 that do not have the second sinker 138. FIG. 4C-4D show the first method of forming the second sinker 138 using diffusion of PSG. This first method is similar or same as the first method illustrated and described for the first sinker 128 of the first isolation trench 110 in connection with FIG. 3C-3D above. FIG. 4E shows the second method of forming the second sinker 138 using ion implantation. This second method is similar or same as the second method illustrated and described for first sinker 128 of the first isolation trench 110 in connection with FIG. 3E above.

In the examples of FIGS. 4D and 4E, the second sinker 138 extends through the upper semiconductor substrate layer 108 at least to the upper main surface 106_4 of the patterned buried semiconductor substrate layer 106. In other examples, the second sinker 138 does not reach the upper main surface 106_4 of the patterned buried semiconductor substrate layer 106. In the examples of FIGS. 4D and 4E, no first sinker 128 is formed at the first isolation trench 110. In other examples, the first sinker 128 may be formed at the first isolation trench 110 similar or same as illustrated and described in connection with FIG. 3C-3E above. The first sinker 128 and the second sinker 138 may be formed concurrently or consecutively. A concurrent forming of the first sinker 128 and the second sinker 138 allows a cost-effective manufacturing of the semiconductor device 400.

FIG. 4F shows the semiconductor device 400 after the second etching step of the two-step etching process has been performed. During the second etching step, trench depths of the first isolation trench 110 and of the second isolation trench 130 are extended using the hard mask 340 as a mask layer. After the second etching step, the first isolation trench 110 has its final first depth d1 and the second isolation trench 130 has its final second depth d2. The first depth d1 is larger than the second depth d2. In the example of FIG. 4F, the second isolation trench 130 extends through the upper semiconductor substrate layer 108 and through the patterned buried semiconductor substrate layer 106 into the lower semiconductor substrate layer 104. In other examples, the second isolation trench 130 extends through the upper semiconductor substrate layer 108 at least to the upper main surface 106_4 of the patterned buried semiconductor substrate layer 106 but does not extend through the patterned buried semiconductor substrate layer 106.

FIG. 4G shows the semiconductor device 400 after the first insulating material 112 and the first electrically conductive material 114 have been formed in the first isolation trench 110 and after the second insulating material 132 has been formed in the second isolation trench 130. The second insulating material 132 may be similar or same as the first insulating material 112. The second insulating material 132 covers the inner sidewall 134_1, 136_1 and the bottom of the second isolation trench 130. In the example of FIG. 4G, the second isolation trench 130 is completely filled with the second insulating material 132. In other examples, the second isolation trench 130 may be partly filled with second electrically conductive material similar or same as the first electrically conductive material 114. As further illustrated in FIG. 4G, the hard mask 340 has been removed from the first main surface 102_1 of the upper semiconductor substrate layer 108. An optional processing step (not illustrated) may be performed before the filling with the first electrically conductive material 114 to form a region having a locally increase dopant concentration at the bottom of the first isolation trench 110.

While in the example of FIG. 4A-4G, the first isolation trench 110 and the second isolation trench 130 are formed concurrently, it should be noted that in other examples, the first isolation trench 110 and the second isolation trench 130 may be formed in consecutive processing steps. A concurrent forming of the first isolation trench 110 and the second isolation allows a cost-effective manufacturing of the semiconductor device 400.

FIG. 5A-5F schematically illustrate a series of cross-sectional views of an exemplary method of manufacturing a further semiconductor device 500. In one example, the method as will be described in connection with FIG. 5A-5F may be used to manufacture at least part of a semiconductor device similar to one of the semiconductor devices 100D-100G, 200B as illustrated and described in connection with FIG. 1D-1G, 2B above. In another example, the method as will be described in connection with FIG. 5A-5F may be used to manufacture at least part of a different semiconductor device.

The method of manufacturing of FIG. 5A-5F is similar to the method of manufacturing of FIG. 4A-4G. Differently, the first isolation trench 110 is formed in a one-step etching process and the second isolation trench 130 is formed in a one-step etching process. In one example, the first isolation trench 110 and the second isolation trench 130 are formed concurrently in the one-step etching process. A concurrent forming of the first isolation trench 110 and the second isolation trench 130 allows a cost-effective manufacturing of the semiconductor device 500.

The semiconductor device 500 of FIG. 5A is similar or same as the semiconductor device 400 of FIG. 4A with the structured mask layer 342 having the first and second opening and with the hard mask 340.

The semiconductor device 500 of FIG. 5B is similar or same as the semiconductor device 400 of FIG. 4B. Differently, the first isolation trench 110 is etched to the final first depth d1 during the one-step etching process. Also the second isolation trench 130 is etched to the final second depth d2 during the one-step etching process.

FIG. 5C-5E schematically illustrate a series of cross-sectional views of two different methods of manufacturing the optional second sinker 138 that is formed along at least part of an outer sidewall 134_2, 136_2 of the second isolation trench 130. The two different methods are similar or same as the two different methods of FIG. 4C-4E. An optional first sinker 128 (not illustrated) may be formed at the first isolation trench 110 similar or same as described in connection with FIG. 4C-4E above.

The semiconductor device 500 of FIG. 5F is similar or same as the semiconductor device 400 of FIG. 4G with insulating material 112, 132 and electrically conductive material 114 formed in the first isolation trench 110 and in the second isolation trench 130. The hard mask 340 has been removed and an optional processing step (not illustrated) may be performed to form a region having a locally increase dopant concentration at the bottom of the first isolation trench 110.

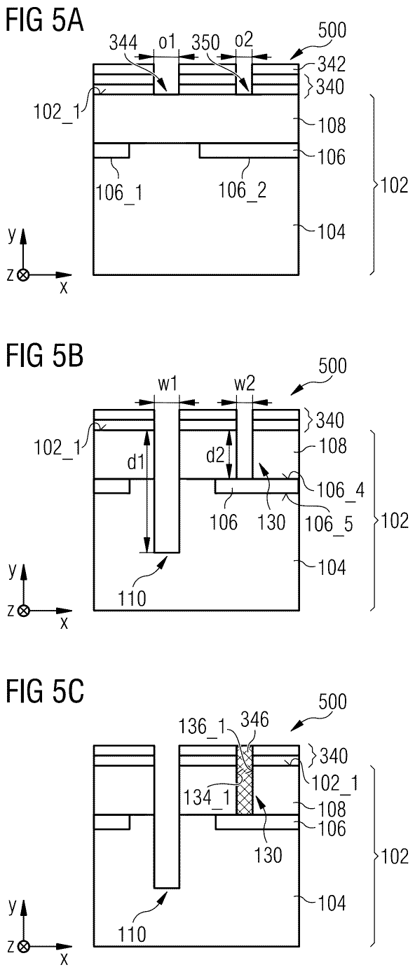

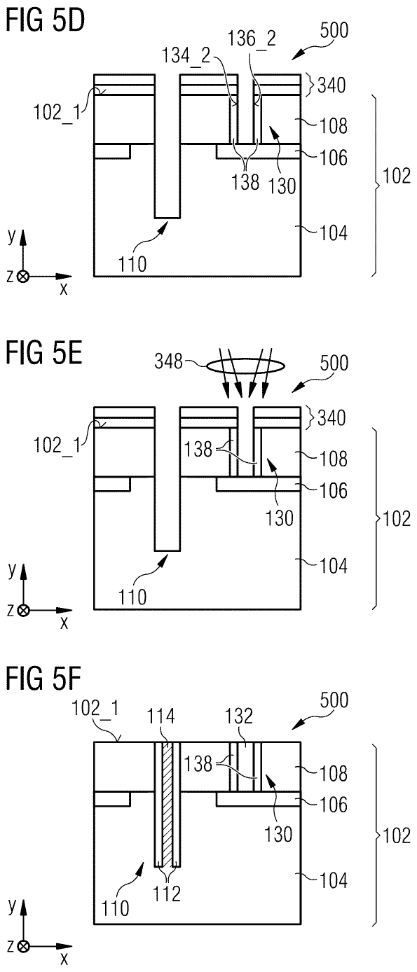

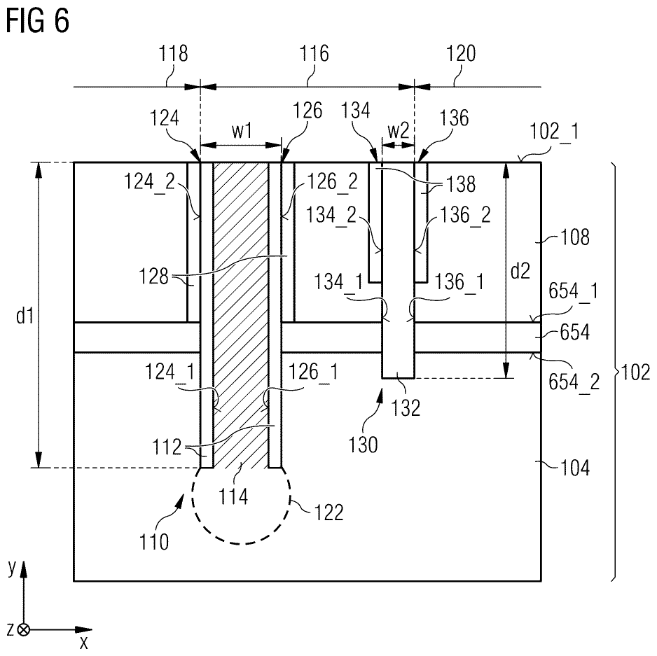

FIG. 6 schematically illustrates a further partial cross-sectional view of an exemplary semiconductor device 600. The semiconductor device 600 includes a semiconductor substrate 102. The semiconductor substrate 102 includes a lower semiconductor substrate layer 104 of the first conductivity type and an upper semiconductor substrate layer 108. The semiconductor substrate 102, the lower semiconductor substrate layer 104 and the upper semiconductor substrate layer 108 are similar or same as the semiconductor substrate 102, the lower semiconductor substrate layer 104 and the upper semiconductor substrate layer 108 of FIG. 1A. The semiconductor substrate 102 further includes a buried semiconductor substrate layer 654 of the second conductivity type that is interposed between the lower semiconductor substrate layer 104 and the upper semiconductor substrate layer 108 in a vertical direction y. The buried semiconductor substrate layer 654 is similar but not identical to the patterned buried semiconductor substrate layer 106 of FIG. 1A. The buried semiconductor substrate layer 654 of FIG. 6 does not include the intermediate region 106_3 of the patterned buried semiconductor substrate layer 106 of FIG. 1A.

A first isolation trench 110 is provided at a first main surface 102_1 of the upper semiconductor substrate layer 108. The first isolation trench 110 extends in the vertical direction y through the upper semiconductor substrate layer 108 and through the buried semiconductor substrate layer 654 into the lower semiconductor substrate layer 104. The first isolation trench 110 is similar or same as to the first isolation trench 110 of FIG. 1A. However, the first isolation trench 110 is integrated differently into the semiconductor substrate 102 of FIG. 6 than the first isolation trench 110 into the semiconductor substrate 102 of FIG. 1A. The first isolation trench 110 of FIG. 6 adjoins the buried semiconductor substrate layer 654 and there is no distance between a sidewall 124, 126 of the first isolation trench 110 and the buried semiconductor substrate layer 654. That means, the first isolation trench 110 separates the buried semiconductor substrate layer 654 of a second functional device region 120 from the buried semiconductor substrate layer 654 of a first functional device region 118. The first isolation trench 110 of FIG. 6 includes a first insulating material 112 formed at an inner sidewall 124_1, 126_1 of the first isolation trench 110, and the first isolation trench 110 is filled with a first electrically conductive material 114 similar to the first isolation trench 110 of FIG. 1A.

An optional first sinker 128 is formed at the upper main surface 102_1 of the upper semiconductor substrate layer 108 and extends in the vertical direction y along at least part of an outer sidewall 124_2, 126_2 of the first isolation trench 110. The first sinker 128 of FIG. 6A is similar to the first sinker 128 of FIG. 1C. Differently, the first sinker 128 of FIG. 6A extends to an upper main surface 654_1 of the buried semiconductor substrate layer 654. Generally, the first sinker 128 extends at least to the upper main surface 654_1 of the buried semiconductor substrate layer 654. The first sinker 128 of FIG. 6A contacts the buried semiconductor substrate layer 654 to provide a low ohmic electrical connection to the buried semiconductor substrate layer 654.

An optional region 122 of the lower semiconductor substrate layer 104 is arranged at a bottom of the first isolation trench 110. The region 122 has a locally increased dopant concentration to provide an improved electrical contact of the first electrically conductive material 114 to the lower semiconductor substrate layer 104.

The semiconductor device 600 includes a second isolation trench 130 formed at the first main surface 102_1 of the upper semiconductor substrate layer 108 and extending in the vertical direction y. The second isolation trench 130 is similar or same as the second isolation trench 130 of FIG. 1D-1G and includes a second insulating material 132 formed at an inner sidewall 134_1, 136_1 and a bottom of the second isolation trench 130. In the example of FIG. 6, the second isolation trench 130 extends through the upper semiconductor substrate layer 108 and through the buried semiconductor substrate layer 654 into the lower semiconductor substrate layer 104. In other examples, the second isolation trench 130 extends through the upper semiconductor substrate layer 108 at least to the upper main surface 654_1 of the buried semiconductor substrate layer 654 but does not extend through the buried semiconductor substrate layer 654. The first isolation trench 110 has a first width w1, the second isolation trench 130 has a second width w2 and the first width w1 is larger than the second width w2. The first width w1 and the second width w2 may be measured at a position at the first main surface 102_1 of the upper semiconductor substrate layer 108. Besides, the first isolation trench 110 has a first depth d1, the second isolation trench 130 has a second depth d2 and the first depth d1 is larger than the second depth d2. The first depth d1 and the second depth d2 may be measured starting from a position at the first main surface 102_1 of the upper semiconductor substrate layer 108 to the bottom of the first isolation trench 110 and the second isolation trench 130, respectively.

As illustrated in FIG. 6, a second sinker 138 is formed at the upper main surface 102_1 of the upper semiconductor substrate layer 108 and extending in the vertical direction y along at least part of an outer sidewall 134_2, 136_2 of the second isolation trench 130. The second sinker 138 is similar or same as the second sinker 138 of FIG. 1G and extends from the upper main surface 102_1 of the upper semiconductor substrate layer 108 into the upper semiconductor substrate layer 108. The second sinker 138 does not extend to the upper main surface 654_1 of the buried semiconductor substrate layer 654.

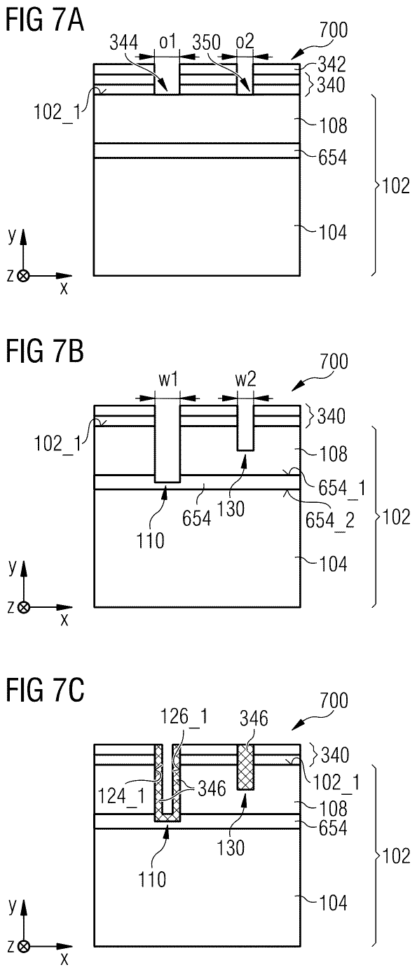

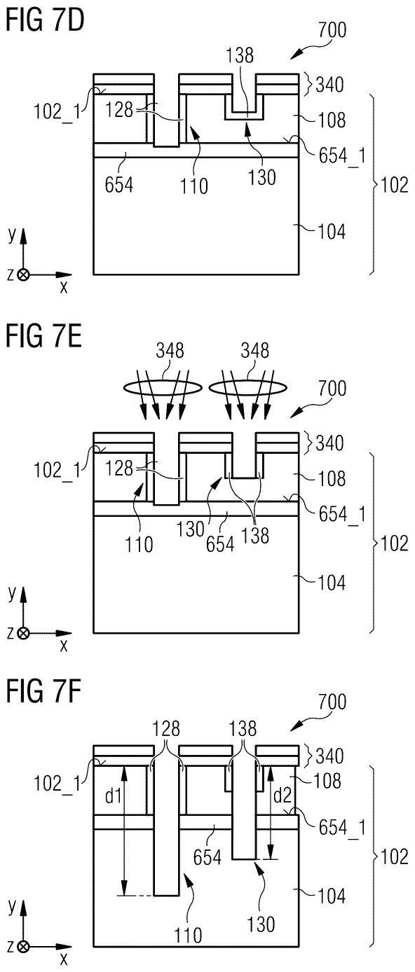

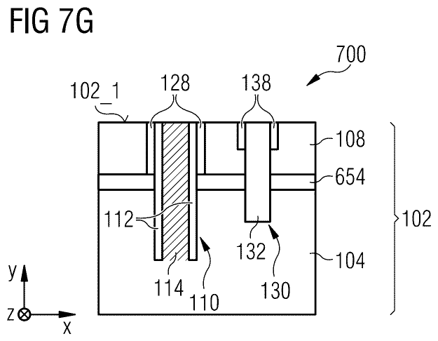

FIG. 7A-7G schematically illustrate a series of cross-sectional views of an exemplary method of manufacturing a further semiconductor device 700. In one example, the method as will be described in connection with FIG. 7A-7G may be used to manufacture at least part of a semiconductor device similar to the semiconductor device 600 illustrated and described in connection with FIG. 6 above. In another example, the method as will be described in connection with FIG. 7A-7G may be used to manufacture at least part of a different semiconductor device. The method of manufacturing of FIG. 7A-7G is similar but not the same as the method of manufacturing of FIG. 4A-4G.

The semiconductor device 700 of FIG. 7A is similar to the semiconductor device 400 of FIG. 4A with a structured mask layer 342 having a first and a second opening and with a hard mask 340. Differently, the buried semiconductor substrate layer 654 of FIG. 7A does not include an intermediate region of the buried semiconductor substrate layer 654 below the first opening having a first width o1.

The semiconductor device 700 of FIG. 7B is similar to the semiconductor device 400 of FIG. 4B. Differently, the first isolation trench 110 extends through the upper semiconductor substrate layer 108 into an intermediate trench depth that is between the upper main surface 654_1 of the buried semiconductor substrate layer 654 and the lower main surface 654_2 of the buried semiconductor substrate layer 106 after a first etching step of a two-step etching process. Generally, the first isolation trench 110 may not extend deeper than the lower main surface 654_2 of the buried semiconductor substrate layer 654 after the first etching step. A further difference to FIG. 4B is that, during the first etching step, the second isolation trench 130 is etched to an intermediate trench depth that is above the upper main surface 654_1 of the buried semiconductor substrate layer 654. That means, the second isolation trench 130 extends into the upper semiconductor substrate layer 108 but does not reach the upper main surface 654_1 of the buried semiconductor substrate layer 654 after the first etching step.

FIG. 7C-7E schematically illustrate a series of cross-sectional views of two different methods of manufacturing a second sinker 138 that extends from the upper main surface 102_1 of the upper semiconductor substrate layer 108 along at least part of an outer sidewall 134_2, 136_2 of the second isolation trench 130 similar to the semiconductor device 400 of FIG. 4C-4E. Differently, the second sinker 138 of FIG. 7C-7E extends from the upper main surface 102_1 of the upper semiconductor substrate layer 108 into the upper semiconductor substrate layer 108 but does not extend to the upper main surface 654_1 of the buried semiconductor substrate layer 654. A further difference to FIG. 4C-4E is that an optional first sinker 128 is formed at the first isolation trench 110 similar or same as illustrated and described in connection with FIG. 3C-3E above. The optional first sinker 128 extends from the upper main surface 102_1 of the upper semiconductor substrate layer 108 to the upper main surface 654_1 of the buried semiconductor substrate layer 654 to provide a low ohmic electrical connection to the buried semiconductor substrate layer 654. While in the example of FIG. 3C, the first isolation trench 110 is completely filled with PSG, in other examples, the first isolation trench 110 is only partly filled with PSG. In the example of FIG. 7C, PSG is formed to cover an inner sidewall 124_1, 126_1 and a bottom of the first isolation trench 110. The first sinker 128 and the second sinker 138 may be formed concurrently or consecutively. A concurrent forming of the first sinker 128 and the second sinker 138 allows a cost-effective manufacturing of the semiconductor device 700.

The semiconductor device 700 of FIG. 7F is similar to the semiconductor device 400 of FIG. 4F with the extension of the trench depths of the first isolation trench 110 and the second isolation trench 130 during a second etching step of the two-step etching process. After the second etching step, the first isolation trench 110 has its final first depth d1 and the second isolation trench 130 has its final second depth d2. The first depth d1 is larger than the second depth d2. An optional processing step (not illustrated) may be performed to form a region having a locally increase dopant concentration at the bottom of the first isolation trench 110.

The semiconductor device 700 of FIG. 7G is similar to the semiconductor device 400 of FIG. 4G with the filling of the first isolation trench 110 and the second isolation trench 130 with first insulating material 112, second insulating material 132, first electrically conductive material 114 and optional second electrically conductive material (not illustrated).

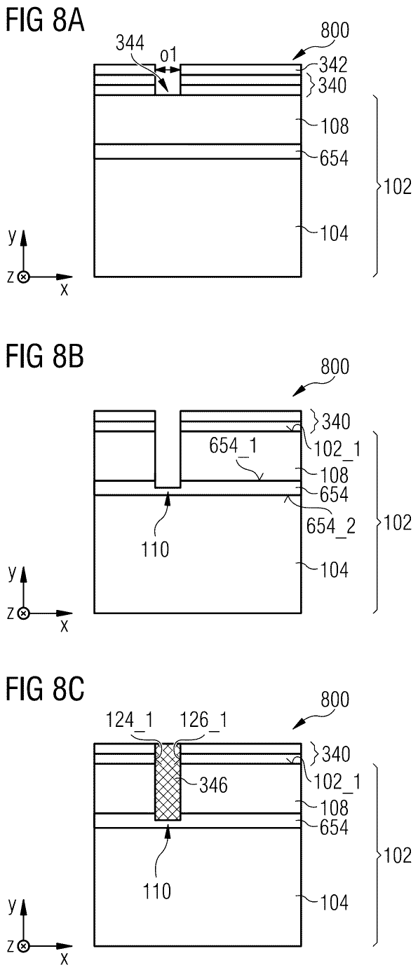

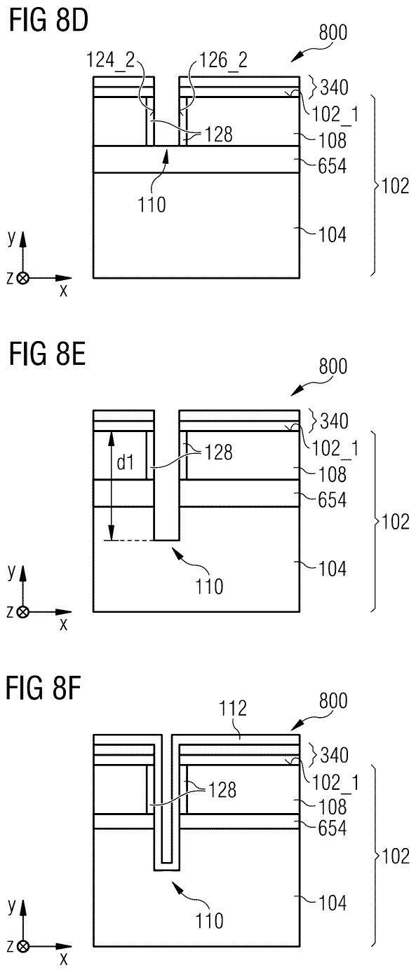

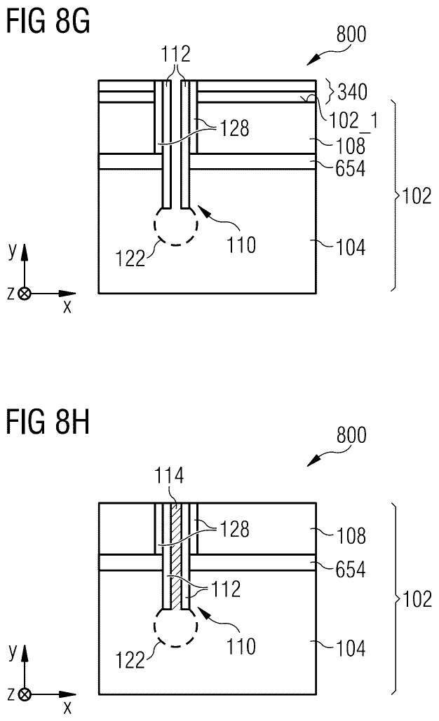

FIG. 8A-8H schematically illustrate a series of cross-sectional views of an exemplary method of manufacturing a further semiconductor device 800. The method of manufacturing of FIG. 8A-8H is similar to the method of manufacturing as illustrated and described in connection with FIG. 3A-3D and FIG. 3F-3I. Differently, the buried semiconductor substrate layer 654 of the semiconductor device 800 does not include an intermediate region of a buried semiconductor substrate layer 654 below a first opening having a first width o1.

In FIG. 8A-8D, a first isolation trench 110 is etched to an intermediate trench depth in a first etching step of a two-step etching process. A first sinker 128 is formed by using PSG 346. While in the example of FIG. 8C, the first isolation trench 110 is completely filled with PSG 346, in other examples, the first isolation trench 110 is only partly filled with PSG 346 as illustrated and described in connection with FIG. 7C above. In a second etching step of FIG. 8E, a trench depth of the first isolation trench 110 is extended to its final depth d1. In FIG. 8F, the first isolation trench 110 is filled with first insulating material 112. In FIG. 8G, an optional region 122 that has a locally increased dopant concentration is formed at a bottom of the first isolation trench 110. In FIG. 8H, the first isolation trench 110 is filled with first electrically conductive material 114.

While in the example of FIG. 8A-8H, the first isolation trench 110 is formed using a two-step etching process, in other examples, a one-step etching process may be used. In some examples, a second isolation trench (not illustrated) may be formed that is similar or same as the second isolation trench 130 illustrated and described in connection with several examples above. The first isolation trench 110 and the second isolation trench 130 may be formed concurrently. A second sinker (not illustrated) may be formed using PSG that is similar or same as the second sinker 138 illustrated and described in connection with several examples above. The first sinker 128 and the second sinker 138 may be formed concurrently.

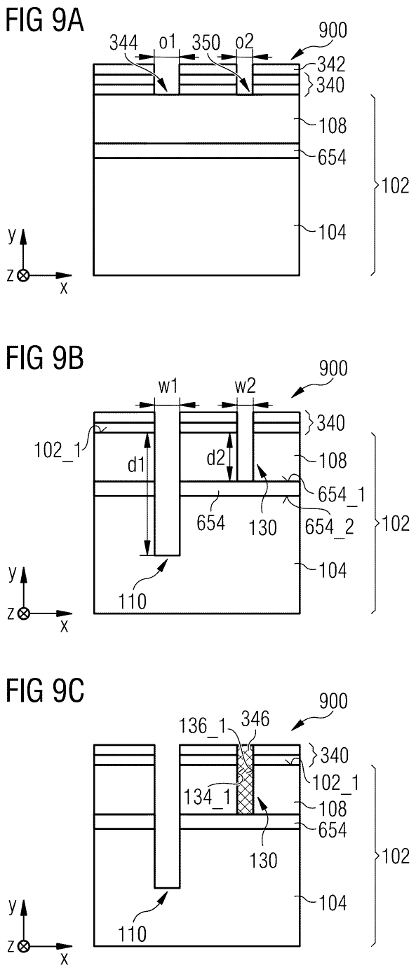

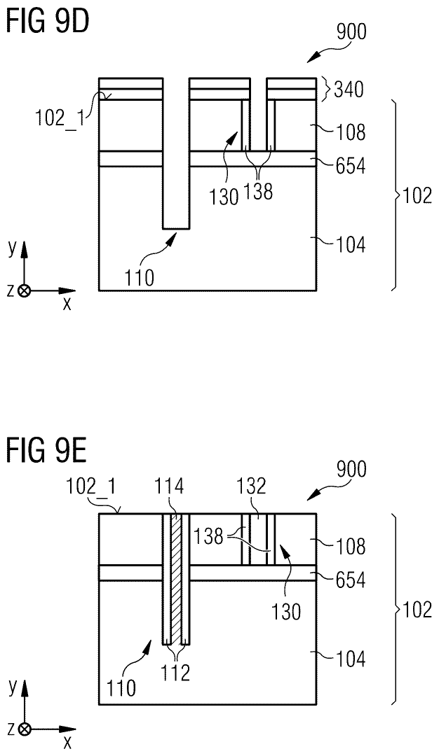

FIG. 9A-9E schematically illustrate a series of cross-sectional views of an exemplary method of manufacturing a further semiconductor device 900. The method of manufacturing of FIG. 9A-9E is similar to the method of manufacturing as illustrated and described in connection with FIG. 3A-3D and FIG. 3F. Differently, the buried semiconductor substrate layer 654 of the semiconductor device 900 does not include an intermediate region of a buried semiconductor substrate layer 654 below a first opening having a first width o1.

In FIG. 9A-9D, a first isolation trench 110 and a second isolation trench 130 are etched. A second sinker 138 is formed by using PSG 346. In FIG. 9E, the first isolation trench 110 and the second isolation trench 130 are filled with first insulating material 112, second insulating material 132 and first electrically conductive material 114.

While in the example of FIG. 9A-9D, the first isolation trench 110 and the second isolation trench 130 are formed using a one-step etching process, in other examples, a multiple step etching process may be used. The first isolation trench 110 and the second isolation trench 130 may be formed concurrently. An optional first sinker 128 (not illustrated) may be formed similar or same as illustrated and described in connection with FIG. 3C-3E above. The optional first sinker 128 may be formed using PSG. The first sinker 128 and the second sinker 138 may be formed concurrently. An optional processing step (not illustrated) may be performed to form a region having a locally increase dopant concentration at the bottom of the first isolation trench 110.

The methods of manufacturing the semiconductor devices 300, 400, 500, 700, 800, 900 as illustrated and described in connection with FIG. 3A-3I, 4A-4G, 5A-5F, 7A-7G, 8A-8H, 9A-9E are provided as examples. The manufacturing steps described do not necessarily have to be carried out in the order given unless noted otherwise. Some of the manufacturing steps may be carried out concurrently. There may be different, additional and/or intermediate manufacturing steps. In one example, well regions and/or doped regions may be formed in the upper semiconductor substrate layer 108 to form parts of functional devices. These well regions and/or doped regions may be formed by diffusion and/or implantation. In one example, interface regions may be formed to electrically isolate device structures from each other. These interface regions may be at least partly formed within the upper semiconductor substrate layer 108. These interface regions may include shallow trench isolation (STI) and/or local oxidation of silicon (LOCOS) structures.

Examples of the present invention are summarized here. Other examples can also be understood from the entirety of the specification and the claims filed herein.
Example 1: A semiconductor device, comprising:
a lower semiconductor substrate layer of a first conductivity type;
an upper semiconductor substrate layer;
a patterned buried semiconductor substrate layer interposed between the lower semiconductor substrate layer and the upper semiconductor substrate layer, wherein the patterned buried semiconductor substrate layer comprises:
   i. a first portion of a second conductivity type,
   ii. a second portion of a second conductivity type that is laterally spaced apart from the first portion, and
   iii. an intermediate region arranged laterally between the first portion and the second portion; and
a first isolation trench formed at an upper main surface of the upper semiconductor substrate layer and extending in a vertical direction through the upper semiconductor substrate layer and through the intermediate region of the patterned buried semiconductor substrate layer into the lower semiconductor substrate layer,
   i. wherein the first isolation trench is spaced apart from the first portion of the patterned buried semiconductor substrate layer and from the second portion of the patterned buried semiconductor substrate layer;
   ii. wherein the first isolation trench comprises a first insulating material formed at an inner sidewall of the first isolation trench, and
   iii. wherein the first isolation trench is filled with a first electrically conductive material.
Example 2: The semiconductor device of example 1, further comprising: a first sinker formed at the upper main surface of the upper semiconductor substrate layer and extending in the vertical direction along at least part of an outer sidewall of the first isolation trench.
Example 3: The semiconductor device of example 2, wherein a highly doped portion of the first sinker is spaced apart from the first portion of the patterned buried semiconductor substrate layer and from the second portion of the patterned buried semiconductor substrate layer.
Example 4: The semiconductor device of any of examples 2 or 3, wherein the first sinker extends from the upper main surface of the upper semiconductor substrate layer at least to a depth defined by an upper main surface of the patterned buried semiconductor substrate layer.
Example 5: The semiconductor device of any of the preceding examples, further comprising: a region of the lower semiconductor substrate layer arranged at a bottom of the first isolation trench, wherein the region has a locally increased dopant concentration.
Example 6: The semiconductor device of any of the preceding examples, further comprising: a second isolation trench formed at the first main surface of the upper semiconductor substrate layer and extending in the vertical direction, wherein the second isolation trench comprises a second insulating material formed at an inner sidewall and a bottom of the second isolation trench.
Example 7: The semiconductor device of example 6, wherein the second isolation trench extends through the upper semiconductor substrate layer and through the patterned buried semiconductor substrate layer into the lower semiconductor substrate layer.
Example 8: The semiconductor device of example 6, wherein the second isolation trench extends through the upper semiconductor substrate layer at least to an upper main surface of the patterned buried semiconductor substrate layer but does not extend through the patterned buried semiconductor substrate layer.
Example 9: The semiconductor device of any of examples 6 to 8, wherein the second isolation trench has a second width and the first isolation trench has a first width larger than the second width and/or wherein the second isolation trench has a second depth and the first isolation trench has a first depth larger than the second depth.
Example 10: The semiconductor device of any of examples 6 to 9, further comprising: a second sinker formed at the upper main surface of the upper semiconductor substrate layer and extending in the vertical direction along at least part of an outer sidewall of the second isolation trench.
Example 11: The semiconductor device of example 10, wherein the second sinker extends from the upper main surface of the upper semiconductor substrate layer through the upper semiconductor substrate layer at least to an upper main surface of the patterned buried semiconductor substrate layer.
Example 12: A method of manufacturing a semiconductor device, comprising: forming a buried semiconductor substrate layer over a lower semiconductor substrate layer of a first conductivity type; patterning the buried semiconductor substrate layer to form a first portion of a second conductivity type, a second portion of the second conductivity type that is laterally spaced apart from the first portion, and an intermediate region that is arranged laterally between the first portion and the second portion; forming an upper semiconductor substrate layer over the patterned buried semiconductor substrate layer; forming a first isolation trench extending in a vertical direction from an upper main surface of the upper semiconductor substrate layer through the upper semiconductor substrate layer and through the intermediate region of the patterned buried semiconductor substrate layer into the lower semiconductor substrate layer, wherein the first isolation trench is spaced apart from the first portion of the patterned buried semiconductor substrate layer and from the second portion of the patterned buried semiconductor substrate layer; forming a first insulating material which covers an inner sidewall of the first isolation trench, and filling the first isolation trench with a first electrically conductive material.
Example 13: The method of example 12, further comprising: prior to filling the first isolation trench with the first electrically conductive material, introducing dopants of the first conduction type into the first isolation trench to form a region of the lower semiconductor substrate layer arranged at a bottom of the first isolation trench, wherein the region has a locally increased dopant concentration.
Example 14: The method of any of examples 12 or 13, wherein forming the first isolation trench comprises a one-step etching process.
Example 15: The method of any of examples 12 or 13, wherein forming the first isolation trench comprises a multiple step etching process, wherein in a first etching step of the multiple step etching process, the first isolation trench is etched to an intermediate trench depth, and wherein in a second etching step of the multiple step etching process, a trench depth of the first isolation trench is extended.
Example 16: The method of any of examples 12 to 15, further comprising: forming a first sinker extending in a vertical direction from the upper main surface of the upper semiconductor substrate layer along at least part of an outer sidewall of the first isolation trench.
Example 17: The method of example 16, wherein a highly doped portion of the first sinker is spaced apart from the first portion of the patterned buried semiconductor substrate layer and from the second portion of the patterned buried semiconductor substrate layer.
Example 18: The method of any of examples 16 or 17, wherein the first sinker extends from the upper main surface of the upper semiconductor substrate layer at least to a depth defined by an upper main surface of the patterned buried semiconductor substrate layer.
Example 19: The method of any of examples 16 to 18, wherein forming the first sinker comprises: prior to forming the first insulating material, implanting ions through the inner sidewall of the first isolation trench into the outer sidewall of the first isolation trench.
Example 20: The method of any of examples 16 to 18, wherein forming the first sinker comprises: prior to forming the first insulating material, forming PSG (phosphosilicate glass) which covers the inner sidewall and a bottom of the first isolation trench, and diffusing phosphorous of the PSG into the outer sidewall of the first isolation trench.
Example 21: The method of any of examples 16 to 20 in combination with example 14, wherein the first sinker is formed after the one-step etching process.
Example 22: The method of any of examples 16 to 20 in combination with example 15, wherein the first sinker is formed after the first etching step of the multiple step etching process and prior to the second etching step of the multiple step etching process.
Example 23: The method of any of examples 12 to 22, further comprising: forming a second isolation trench extending in a vertical direction from an upper main surface of the upper semiconductor substrate layer, and forming a second insulating material which covers an inner sidewall and a bottom of the second isolation trench.
Example 24: The method of example 23, wherein the second isolation trench extends through the upper semiconductor substrate layer and through the patterned buried semiconductor substrate layer into the lower semiconductor substrate layer.
Example 25: The method of example 23, wherein the second isolation trench extends through the upper semiconductor substrate layer at least to an upper main surface of the patterned buried semiconductor substrate layer but does not extend through the patterned buried semiconductor substrate layer.
Example 26: The method of any of examples 23 to 25, wherein the second isolation trench has a second width and the first isolation trench has a first width larger than the second width and/or wherein the second isolation trench has a second depth and the first isolation trench has a first depth larger than the second depth.
Example 27: The method of any of examples 23 to 26, wherein forming the second isolation trench comprises a one-step etching process.
Example 28: The method of any of examples 23 to 26, wherein forming the second isolation trench comprises a multiple step etching process, wherein in a first etching step of the multiple step etching process, the second isolation trench is etched to an intermediate trench depth, and wherein in a second etching step of the multiple step etching process, a trench depth of the second isolation trench is extended.
Example 29: The method of any of examples 23 to 28, wherein the first isolation trench and the second isolation trench are formed concurrently.
Example 30: The method of any of examples 23 to 29, further comprising: forming a second sinker extending in a vertical direction from the upper main surface of the upper semiconductor substrate layer along at least part of an outer sidewall of the second isolation trench.
Example 31: The method of example 30, wherein the second sinker extends from the upper main surface of the upper semiconductor substrate layer through the upper semiconductor substrate layer at least to an upper main surface of the patterned buried semiconductor substrate layer.
Example 32: The method of any of examples 30 or 31, wherein forming the second sinker comprises: prior to forming the second insulating material, implanting ions through the inner sidewall of the second isolation trench into the outer sidewall of the second isolation trench.
Example 33: The method of any of examples 30 or 31, wherein forming the second sinker comprises: prior to forming the second insulating material, forming PSG (phosphosilicate glass) which covers at least the inner sidewall and a bottom of the second isolation trench, and diffusing phosphorous of the PSG into the outer sidewall of the second isolation trench.
Example 34: The method of any of examples 30 to 33 in combination with example 27, wherein the second sinker is formed after the one-step etching process of the second isolation trench.
Example 35: The method of any of examples 30 to 33 in combination with example 28, wherein the second sinker is formed after the first etching step of the multiple step etching process of the second isolation trench and prior to the second etching step of the multiple step etching process of the second isolation trench.
Example 36: The method of any of examples 30 to 35 in combination with example 16, wherein the first sinker and the second sinker are formed concurrently.
Example 37: A semiconductor device, comprising: a lower semiconductor substrate layer of a first conductivity type; an upper semiconductor substrate layer; a buried semiconductor substrate layer of a second conductivity type interposed between the lower semiconductor substrate layer and the upper semiconductor substrate layer, a first isolation trench formed at an upper main surface of the upper semiconductor substrate layer and extending in a vertical direction through the upper semiconductor substrate layer and through the buried semiconductor substrate layer into the lower semiconductor substrate layer, wherein the first isolation trench comprises a first insulating material formed at an inner sidewall of the first isolation trench, and wherein the first isolation trench is filled with a first electrically conductive material, a second isolation trench formed at the first main surface of the upper semiconductor substrate layer and extending in the vertical direction, wherein the second isolation trench comprises a second insulating material formed at an inner sidewall and a bottom of the second isolation trench, and a second sinker formed at the upper main surface of the upper semiconductor substrate layer and extending in the vertical direction along at least part of an outer sidewall of the second isolation trench, wherein the second sinker extends from the upper main surface of the upper semiconductor substrate layer into the upper semiconductor substrate layer but does not extend to an upper main surface of the buried semiconductor substrate layer.
Example 38: The semiconductor device of example 37, further comprising: a first sinker formed at the upper main surface of the upper semiconductor substrate layer and extending in the vertical direction along at least part of an outer sidewall of the first isolation trench.
Example 39: The semiconductor device of example 38, wherein the first sinker extends from the upper main surface of the upper semiconductor substrate layer at least to the upper main surface of the buried semiconductor substrate layer.
Example 40: The semiconductor device of any of examples 37 to 39, further comprising: a region of the lower semiconductor substrate layer arranged at a bottom of the first isolation trench, wherein the region has a locally increased dopant concentration.
Example 41: The semiconductor device of any of examples 37 to 40, wherein the second isolation trench extends through the upper semiconductor substrate layer and through the buried semiconductor substrate layer into the lower semiconductor substrate layer.
Example 42: The semiconductor device of any of examples 37 to 40, wherein the second isolation trench extends through the upper semiconductor substrate layer at least to the upper main surface of the buried semiconductor substrate layer but does not extend through the buried semiconductor substrate layer.
Example 43: The semiconductor device of any of examples 37 to 42, wherein the second isolation trench has a second width and the first isolation trench has a first width larger than the second width and/or wherein the second isolation trench has a second depth and the first isolation trench has a first depth larger than the second depth.
Example 44: A method of manufacturing a semiconductor device, comprising: forming a buried semiconductor substrate layer of a second conductivity type over a lower semiconductor substrate layer of a first conductivity type; forming an upper semiconductor substrate layer over the buried semiconductor substrate layer; forming a first isolation trench extending in a vertical direction from an upper main surface of the upper semiconductor substrate layer through the upper semiconductor substrate layer and through the buried semiconductor substrate layer into the lower semiconductor substrate layer; forming a first insulating material which covers an inner sidewall of the first isolation trench; filling the first isolation trench with a first electrically conductive material; forming a second isolation trench extending in a vertical direction from an upper main surface of the upper semiconductor substrate layer; forming a second insulating material which covers an inner sidewall and a bottom of the second isolation trench; and forming a second sinker extending in a vertical direction from the upper main surface of the upper semiconductor substrate layer along at least part of an outer sidewall of the second isolation trench, wherein the second sinker extends from the upper main surface of the upper semiconductor substrate layer into the upper semiconductor substrate layer but does not extend to an upper main surface of the buried semiconductor substrate layer.
Example 45: The method of example 44, further comprising: prior to filling the first isolation trench with the first electrically conductive material, introducing dopants of the first conduction type into the first isolation trench to form a region of the lower semiconductor substrate layer arranged at a bottom of the first isolation trench, wherein the region has a locally increased dopant concentration.
Example 46: The method of any of examples 44 or 45, wherein forming the first isolation trench comprises a multiple step etching process, wherein in a first etching step of the multiple step etching process, the first isolation trench is etched to an intermediate trench depth, and wherein in a second etching step of the multiple step etching process, a trench depth of the first isolation trench is extended.
Example 47: The method of any of examples 44 to 46, further comprising: forming a first sinker extending in a vertical direction from the upper main surface of the upper semiconductor substrate layer along at least part of an outer sidewall of the first isolation trench.
Example 48: The method of example 47, wherein the first sinker extends from the upper main surface of the upper semiconductor substrate layer at least to the upper main surface of the buried semiconductor substrate layer.
Example 49: The method of any of examples 47 or 48, wherein forming the first sinker comprises: prior to forming the first insulating material, implanting ions through the inner sidewall of the first isolation trench into the outer sidewall of the first isolation trench.
Example 50: The method of any of examples 47 or 48, wherein forming the first sinker comprises: prior to forming the first insulating material, forming PSG (phosphosilicate glass) which covers the inner sidewall and a bottom of the first isolation trench, and diffusing phosphorous of the PSG into the outer sidewall of the first isolation trench.
Example 51: The method of any of examples 47 to 50 in combination with example 46, wherein the first sinker is formed after the first etching step of the multiple step etching process and prior to the second etching step of the multiple step etching process.
Example 52: The method of any of examples 44 to 51, wherein the second isolation trench extends through the upper semiconductor substrate layer and through the buried semiconductor substrate layer into the lower semiconductor substrate layer.
Example 53: The method of any of examples 44 to 51, wherein the second isolation trench extends through the upper semiconductor substrate layer at least to the upper main surface of the buried semiconductor substrate layer but does not extend through the buried semiconductor substrate layer.
Example 54: The method of any of examples 44 to 53, wherein the second isolation trench has a second width and the first isolation trench has a first width larger than the second width and/or wherein the second isolation trench has a second depth and the first isolation trench has a first depth larger than the second depth.
Example 55: The method of any of examples 44 to 54, wherein forming the second isolation trench comprises a multiple step etching process, wherein in a first etching step of the multiple step etching process, the second isolation trench is etched to an intermediate trench depth, and wherein in a second etching step of the multiple step etching process, a trench depth of the second isolation trench is extended.
Example 56: The method of example 55, wherein the second sinker is formed after the first etching step of the multiple step etching process of the second isolation trench and prior to the second etching step of the multiple step etching process of the second isolation trench.
Example 57: The method of any of examples 44 to 56, wherein the first isolation trench and the second isolation trench are formed concurrently.
Example 58: The method of any of examples 44 to 57, wherein forming the second sinker comprises: prior to forming the second insulating material, implanting ions through the inner sidewall of the second isolation trench into the outer sidewall of the second isolation trench.
Example 59: The method of any of examples 44 to 57, wherein forming the second sinker comprises: prior to forming the second insulating material, forming PSG (phosphosilicate glass) which covers at least the inner sidewall and a bottom of the second isolation trench, and diffusing phosphorous of the PSG into the outer sidewall of the second isolation trench.
Example 60: The method of any of examples 47 to 59, wherein the first sinker and the second sinker are formed concurrently.
Example 61: A method of manufacturing a semiconductor device, comprising: forming a buried semiconductor substrate layer of a second conductivity type over a lower semiconductor substrate layer of a first conductivity type; forming an upper semiconductor substrate layer over the buried semiconductor substrate layer; forming a first isolation trench extending in a vertical direction from an upper main surface of the upper semiconductor substrate layer through the upper semiconductor substrate layer and through the buried semiconductor substrate layer into the lower semiconductor substrate layer; forming a first insulating material which covers an inner sidewall of the first isolation trench; filling the first isolation trench with a first electrically conductive material; and forming a first sinker extending in a vertical direction from the upper main surface of the upper semiconductor substrate layer along at least part of an outer sidewall of the first isolation trench, wherein forming the first sinker comprises: prior to forming the first insulating material, forming PSG (phosphosilicate glass) which covers the inner sidewall and a bottom of the first isolation trench, and diffusing phosphorous of the PSG into the outer sidewall of the first isolation trench.
Example 62: The method of example 61, wherein forming the first isolation trench comprises a one-step etching process.
Example 63: The method of example 61, wherein forming the first isolation trench comprises a multiple step etching process, wherein in a first etching step of the multiple step etching process, the first isolation trench is etched to an intermediate trench depth, wherein in a second etching step of the multiple step etching process, a trench depth of the first isolation trench is extended, and wherein the first sinker is formed after the first etching step of the multiple step etching process and prior to the second etching step of the multiple step etching process.
Example 64: The method of any of examples 61 to 63, further comprising: forming a second isolation trench extending in a vertical direction from an upper main surface of the upper semiconductor substrate layer, forming a second insulating material which covers an inner sidewall and a bottom of the second isolation trench, forming a second sinker extending in a vertical direction from the upper main surface of the upper semiconductor substrate layer along at least part of an outer sidewall of the second isolation trench, wherein forming the second sinker comprises: prior to forming the second insulating material, forming PSG (phosphosilicate glass) which covers at least the inner sidewall and a bottom of the second isolation trench, and diffusing phosphorous of the PSG into the outer sidewall of the second isolation trench.
Example 65: The method of example 64, wherein the first isolation trench and the second isolation trench are formed concurrently.
Example 66: A method of manufacturing a semiconductor device, comprising: forming a buried semiconductor substrate layer of a second conductivity type over a lower semiconductor substrate layer of a first conductivity type; forming an upper semiconductor substrate layer over the buried semiconductor substrate layer; forming a first isolation trench extending in a vertical direction from an upper main surface of the upper semiconductor substrate layer through the upper semiconductor substrate layer and through the buried semiconductor substrate layer into the lower semiconductor substrate layer; forming a first insulating material which covers an inner sidewall of the first isolation trench; filling the first isolation trench with a first electrically conductive material; forming a second isolation trench extending in a vertical direction from an upper main surface of the upper semiconductor substrate layer, and forming a second insulating material which covers an inner sidewall and a bottom of the second isolation trench; forming a second sinker extending in a vertical direction from the upper main surface of the upper semiconductor substrate layer along at least part of an outer sidewall of the second isolation trench, wherein forming the second sinker comprises: prior to forming the second insulating material, forming PSG (phosphosilicate glass) which covers at least the inner sidewall and a bottom of the second isolation trench, and diffusing phosphorous of the PSG into the outer sidewall of the second isolation trench.
Example 67: The method of example 66, wherein forming the second isolation trench comprises a one-step etching process.
Example 68: The method of example 66, wherein forming the second isolation trench comprises a multiple step etching process, wherein in a first etching step of the multiple step etching process, the second isolation trench is etched to an intermediate trench depth, wherein in a second etching step of the multiple step etching process, a trench depth of the second isolation trench is extended, and wherein the second sinker is formed after the first etching step of the multiple step etching process and prior to the second etching step of the multiple step etching process.
Example 69: The method of any of examples 66 to 68, wherein the first isolation trench and the second isolation trench are formed concurrently.

While this invention has been described with reference to illustrative examples, this description is not intended to be construed in a limiting sense. Various modifications and combinations of the illustrative examples, as well as other examples of the invention, will be apparent to persons skilled in the art upon reference to the description. It is therefore intended that the appended claims encompass any such modifications or examples.

What is claimed is:

1. A semiconductor device, comprising:
a lower semiconductor substrate layer of a first conductivity type;
an upper semiconductor substrate layer;
a patterned buried semiconductor substrate layer interposed between the lower semiconductor substrate layer and the upper semiconductor substrate layer, wherein the patterned buried semiconductor substrate layer comprises:
a first portion of a second conductivity type;
a second portion of the second conductivity type that is laterally spaced apart from the first portion; and
an intermediate region arranged laterally between the first portion and the second portion; and
a first isolation trench formed at an upper main surface of the upper semiconductor substrate layer and extending in a vertical direction through the upper semiconductor substrate layer and through the intermediate region of the patterned buried semiconductor substrate layer into the lower semiconductor substrate layer,
wherein the first isolation trench is spaced apart from the first portion of the patterned buried semiconductor substrate layer and from the second portion of the patterned buried semiconductor substrate layer,
wherein the first isolation trench comprises a first insulating material formed at an inner sidewall of the first isolation trench,
wherein the first isolation trench is filled with a first electrically conductive material.

2. The semiconductor device of claim 1, further comprising:
a first sinker formed at the upper main surface of the upper semiconductor substrate layer and extending in the vertical direction along at least part of an outer sidewall of the first isolation trench.

3. The semiconductor device of claim 2, wherein a highly doped portion of the first sinker is spaced apart from the first portion of the patterned buried semiconductor substrate layer and from the second portion of the patterned buried semiconductor substrate layer.

4. The semiconductor device of claim 2, wherein the first sinker extends from the upper main surface of the upper semiconductor substrate layer at least to a depth defined by an upper main surface of the patterned buried semiconductor substrate layer.

5. The semiconductor device of claim 1, further comprising:
a region of the lower semiconductor substrate layer arranged at a bottom of the first isolation trench, wherein the region has a locally increased dopant concentration.

6. The semiconductor device of claim 1, further comprising:
a second isolation trench formed at the first main surface of the upper semiconductor substrate layer and extending in the vertical direction, wherein the second isolation trench comprises a second insulating material formed at an inner sidewall and a bottom of the second isolation trench.

7. The semiconductor device of claim 6, wherein the second isolation trench extends through the upper semiconductor substrate layer and through the patterned buried semiconductor substrate layer into the lower semiconductor substrate layer.

8. The semiconductor device of claim 6, wherein the second isolation trench extends through the upper semiconductor substrate layer at least to an upper main surface of the patterned buried semiconductor substrate layer but does not extend through the patterned buried semiconductor substrate layer.

9. The semiconductor device of claim 6, wherein the second isolation trench has a second width and the first isolation trench has a first width larger than the second width, and/or wherein the second isolation trench has a second depth and the first isolation trench has a first depth larger than the second depth.

10. The semiconductor device of claim 6, further comprising:
a second sinker formed at the upper main surface of the upper semiconductor substrate layer and extending in the vertical direction along at least part of an outer sidewall of the second isolation trench.

11. The semiconductor device of claim 10, wherein the second sinker extends from the upper main surface of the upper semiconductor substrate layer through the upper semiconductor substrate layer at least to an upper main surface of the patterned buried semiconductor substrate layer.

12. A method of manufacturing a semiconductor device, the method comprising:
forming a buried semiconductor substrate layer over a lower semiconductor substrate layer of a first conductivity type;
patterning the buried semiconductor substrate layer to form a first portion of a second conductivity type, a second portion of the second conductivity type that is laterally spaced apart from the first portion, and an intermediate region that is arranged laterally between the first portion and the second portion;
forming an upper semiconductor substrate layer over the patterned buried semiconductor substrate layer;
forming a first isolation trench extending in a vertical direction from an upper main surface of the upper semiconductor substrate layer through the upper semiconductor substrate layer and through the intermediate region of the patterned buried semiconductor substrate layer into the lower semiconductor substrate layer, wherein the first isolation trench is spaced apart from the first portion of the patterned buried semiconductor substrate layer and from the second portion of the patterned buried semiconductor substrate layer;
forming a first insulating material which covers an inner sidewall of the first isolation trench; and
filling the first isolation trench with a first electrically conductive material.

13. The method of claim 12, further comprising:
prior to filling the first isolation trench with the first electrically conductive material, introducing dopants of the first conduction type into the first isolation trench to form a region of the lower semiconductor substrate layer arranged at a bottom of the first isolation trench, wherein the region has a locally increased dopant concentration.

14. The method of claim 12, further comprising:
forming a first sinker extending in a vertical direction from the upper main surface of the upper semiconductor substrate layer along at least part of an outer sidewall of the first isolation trench.

15. The method of claim 14, wherein a highly doped portion of the first sinker is spaced apart from the first portion of the patterned buried semiconductor substrate layer and from the second portion of the patterned buried semiconductor substrate layer.

16. The method of claim 14, wherein forming the first sinker comprises:
prior to forming the first insulating material, forming PSG (phosphosilicate glass) which covers the inner sidewall and a bottom of the first isolation trench; and
diffusing phosphorous of the PSG into the outer sidewall of the first isolation trench.

17. The method of claim 12, further comprising:
forming a second isolation trench extending in a vertical direction from an upper main surface of the upper semiconductor substrate layer; and
forming a second insulating material which covers an inner sidewall and a bottom of the second isolation trench.

18. The method of claim 17, wherein the second isolation trench has a second width and the first isolation trench has a first width larger than the second width, and/or wherein the second isolation trench has a second depth and the first isolation trench has a first depth larger than the second depth.

19. The method of claim 17, further comprising:
forming a second sinker extending in a vertical direction from the upper main surface of the upper semiconductor substrate layer along at least part of an outer sidewall of the second isolation trench.

20. The method of claim 19, wherein forming the second sinker comprises:
prior to forming the second insulating material, forming PSG (phosphosilicate glass) which covers at least the inner sidewall and a bottom of the second isolation trench; and
diffusing phosphorous of the PSG into the outer sidewall of the second isolation trench.
